(19) United States
(12) Patent Application Publication
(10) Pub. No.: US 2013/0248803 A1
(43) Pub. Date: Sep. 26, 2013

(54) MOLECULAR MEMORY AND METHOD OF MANUFACTURING THE SAME

(71) Applicants: Kiyohito NISHIHARA, Kanagawa-ken (JP); Tetsuya HAYASHI, Kanagawa-ken (JP)

(72) Inventors: Kiyohito NISHIHARA, Kanagawa-ken (JP); Tetsuya HAYASHI, Kanagawa-ken (JP)

(73) Assignee: Kabushiki Kaisha Toshiba, Tokyo (JP)

(21) Appl. No.: 13/601,200

(22) Filed: Aug. 31, 2012

(30) Foreign Application Priority Data
Mar. 22, 2012 (JP) 2012-065752
Mar. 23, 2012 (JP) 2012-068434

(51) Int. Cl. H01L 45/00

(52) U.S. Cl. CPC H01L 45/142; H01L 45/1608
USPC 257/4; 257/2; 438/382

(57) ABSTRACT

According to one embodiment, a molecular memory includes a first electrode, a second electrode, and a resistance-change molecular chain provided between the first electrode and the second electrode. The first electrode includes a core made of a first conductive material, and a side wall made of a second conductive material different from the first conductive material. The side wall is formed on a side surface of the core. The second electrode is made of a third conductive material different from the first conductive material. The resistance-change molecular chain is bonded to the first conductive material.

### CROSS-REFERENCE TO RELATED APPLICATIONS

This application is based upon and claims the benefit of priority from the prior Japanese Patent Application No. 2012-065752, filed on Mar. 22, 2012 and the prior Japanese Patent Application No. 2012-068434, filed on Mar. 23, 2012; the entire contents of which are incorporated herein by reference.

### FIELD

Embodiments described herein relate generally to a molecular memory and a method of manufacturing the same.

### BACKGROUND

In a non-volatile memory device, such as a NAND flash memory, a memory cell has been miniaturized to improve recording density. However, the miniaturization of the memory cell has reached its limits due to, for example, restrictions in lithography technique. Therefore, a study on a molecular memory using a resistance-change molecular chain as a storage element has been conducted. The resistance-change molecular chain is a molecule whose electrical resistance value is changed when an electric signal, such as a voltage or a current, is input. Since the size of the resistance-change molecular chain is small, it is possible to significantly reduce the size of the memory cell. In order to manufacture the molecular memory as a product, it is important to ensure reliability.

### BRIEF DESCRIPTION OF THE DRAWINGS

FIG. 1 is a perspective view illustrating a molecular memory according to a first embodiment;

FIG. 2 is a cross-sectional view illustrating the molecular memory according to the first embodiment;

FIG. 3 is a diagram illustrating a resistance-change molecular chain according to the first embodiment;

FIGS. 4A to 4D and FIGS. 5A to 5D are cross-sectional views illustrating processes of the method of manufacturing the molecular memory according to the first embodiment;

FIGS. 6A to 6C, FIGS. 7A to 7C, FIGS. 8A to 8C, FIGS. 9A to 9C, FIGS. 10A to 10C, FIGS. 11A to 11C, and FIGS. 12A to 12C are diagrams illustrating processes of the method of manufacturing the molecular memory according to the first embodiment;

FIG. 13 is a cross-sectional view illustrating a molecular memory according to a first comparative example;

FIG. 14 is a perspective view illustrating a molecular memory according to a second embodiment;

FIG. 15 is a cross-sectional view illustrating the molecular memory according to the second embodiment;

FIG. 16 is a perspective view illustrating a molecular memory according to a third embodiment;

FIG. 17 is a cross-sectional view illustrating the molecular memory according to the third embodiment;

FIG. 18 is a diagram illustrating a resistance-change molecular chain according to the third embodiment;

FIGS. 19A to 19C, FIGS. 20A to 20C, FIGS. 21A to 21C, FIGS. 22A to 22C, FIGS. 23A to 23C, FIGS. 24A to 24C, FIGS. 25A to 25C, and FIGS. 26A to 26C are diagrams illustrating processes of the method of manufacturing the molecular memory according to the third embodiment;

FIG. 27 is a cross-sectional view illustrating a molecular memory according to a second comparative example;

FIG. 28 is a perspective view illustrating a molecular memory according to a forth embodiment;

FIG. 29 is a cross-sectional view illustrating the molecular memory according to the forth embodiment;

FIG. 30 is a cross-sectional view illustrating a molecular memory according to a fifth embodiment;

FIG. 31 is a circuit diagram illustrating the molecular memory according to the fifth embodiment;

FIG. 32 is a perspective view illustrating a molecular memory according to a sixth embodiment;

FIG. 33 is a diagram illustrating a general formula of a resistance-change molecular chain according to a modification; and

FIGS. 34A to 34F are diagrams illustrating molecular units capable of forming a molecule in which a π-conjugated system extends in a one-dimensional direction.

### DETAILED DESCRIPTION

In general, according to one embodiment, a molecular memory includes a first electrode, a second electrode, and a resistance-change molecular chain provided between the first electrode and the second electrode. The first electrode includes a core made of a first conductive material, and a side wall made of a second conductive material different from the first conductive material. The side wall is formed on a side surface of the core. The second electrode is made of a third conductive material different from the first conductive material. The resistance-change molecular chain is bonded to the first conductive material.

In general, according to one embodiment, a molecular memory includes a first wiring, a second wiring, and a resistance-change molecular chain. The first wiring is made of a first conductive material and extends in a first direction. The second wiring is made of a second conductive material different from the first conductive material and extends in a second direction intersecting the first direction. The resistance-change molecular chain is provided between the first wiring and the second wiring. A surface of the first wiring located at the second wiring side has a first region and a second region. The first region faces a center of the second wiring in a width direction. The second region faces an end of the second wiring in the width direction. The first region is closer to the second wiring than the second region.

In general, according to one embodiment, a method of manufacturing a molecular memory includes stacking a first conductive film made of a first conductive material, a sacrificial film, and a second conductive film made of a second conductive material different from the first conductive material in this order. The method includes selectively removing an upper portion of the first conductive film, the sacrificial film, and the second conductive film to form a plurality of first stacked bodies extending in a first direction, and performing side etching on the upper portion of the first conductive film such that the width of the upper portion is less than that of the second conductive film. The method includes embedding a first insulating film between the first stacked bodies. The method includes selectively removing the first insulating film, the second conductive film, the sacrificial film, and the first conductive film to form a plurality of second stacked bodies extending in a second direction intersecting the first direction. The method includes removing the sacrificial film to form a gap. The method includes providing a resistance-change molecular chain in the gap. The method includes embedding a second insulating film between the second stacked bodies in which the resistance-change molecular chain is provided. And, the method includes forming a third conductive film extending in the first direction so as to be commonly connected to parts of the second conductive film arranged in the first direction.

Hereinafter, embodiments of the invention will be described with reference to the drawings.

First, a first embodiment will be described.

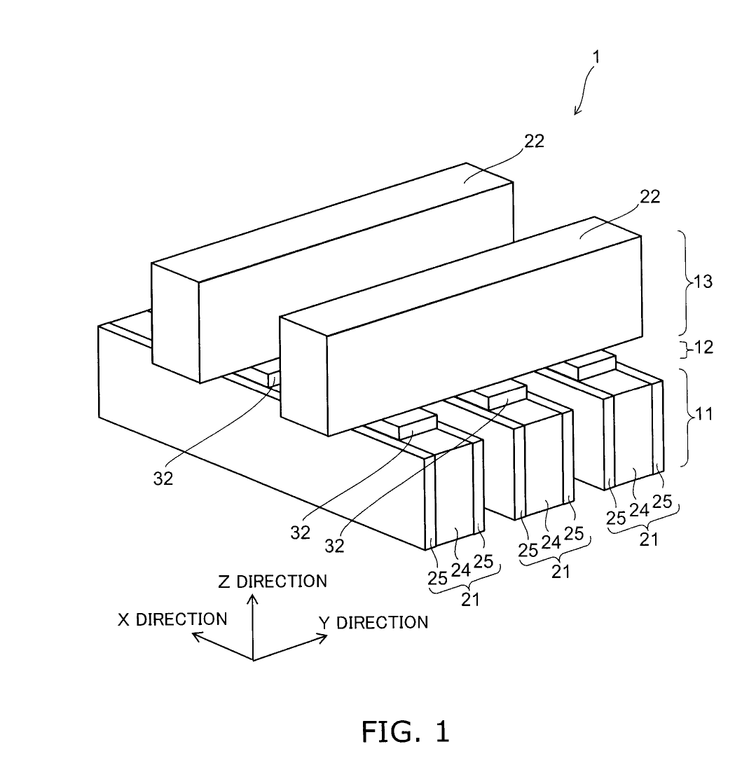

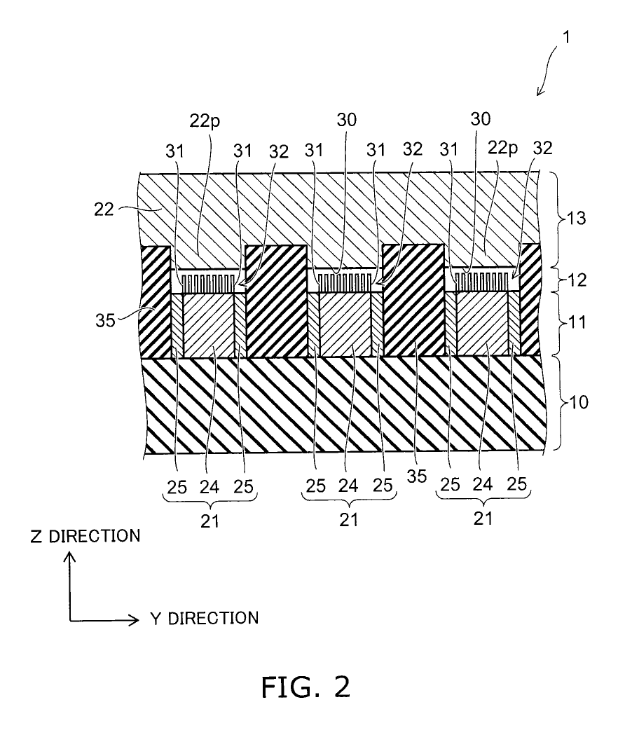

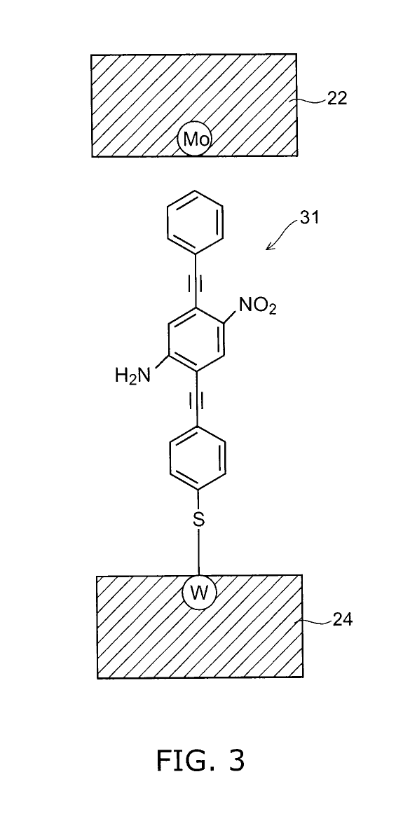

FIG. 1 is a perspective view illustrating a molecular memory according to the embodiment. FIG. 2 is a cross-sectional view illustrating the molecular memory according to the embodiment. FIG. 3 is a diagram illustrating a resistance-change molecular chain according to the embodiment.

For ease of illustration, FIG. 1 shows only a conductive portion and does not show an insulating portion.

As illustrated in FIGS. 1 and 2, in a molecular memory 1 according to the embodiment, an interlayer insulating film 10 is provided on a silicon substrate (not illustrated) and a wiring layer 11, a memory layer 12, and a wiring layer 13 are stacked on the interlayer insulating film 10 in this order. Hereinafter, the stacked direction is referred to as a “Z direction”. In the wiring layer 11, a plurality of wirings 21 extending in one direction (hereinafter, referred to as an “X direction”) are periodically arranged. In the wiring layer 13, a plurality of wirings 22 extending in a direction (hereinafter, referred to as a “Y direction”) intersecting the X direction, for example, in a direction perpendicular to the X direction are periodically arranged. The X direction, the Y direction, and the Z direction are perpendicular to each other.

The wiring 21 includes a core 24 that extends in the X direction and a pair of side walls 25 which are formed on both sides of the core 24 in the width direction, that is, both side surfaces facing the Y direction. The core 24 and the side walls 25 come into contact with each other. The wiring 22 is integrally formed without being divided into a core and side walls. The core 24 is made of, for example, tungsten (W). The side wall 25 and the wiring 22 are made of, for example, molybdenum (Mo). A convex portion 22p is formed in a region of the lower surface of the wiring 22 facing the wiring 21. In FIG. 1, the convex portion 22p is not illustrated. A gap 30 is formed between the closest portions of the wiring 21 and the wiring 22, that is, directly below the convex portion 22p.

In the memory layer 12, an organic molecular layer 32 including a plurality of resistance-change molecular chains 31 is provided between the closest portions of the core 24 and the wiring 22. That is, the organic molecular layer 32 is arranged directly below the core 24 in the gap 30. The resistance-change molecular chain 31 is a molecule whose electrical resistance value is changed when an electric signal, such as a voltage or a current, is input. Each organic molecular layer 32 includes, for example, tens to hundreds of resistance-change molecular chains 31. In addition, the molecular memory 1 includes an interwiring insulating film 35 that is provided so as to embed the wiring 21, the wiring 22, and the organic molecular layer 32. The interlayer insulating film 10 and the interwiring insulating film 35 are made of an insulating material, such as a silicon oxide, alumina, or a silicon nitride.

As illustrated in FIG. 3, the resistance-change molecular chain 31 is, for example, 4-[2-amino-5-nitro-4-(phenylethynyl)phenylethynyl]benzenethiol and has a thiol group (R—SH) at one end thereof. It is easy for a sulfur atom (S) of the thiol group to be bonded to a tungsten atom (W). The resistance-change molecular chain 31 does not include a group which is likely to be bonded to a molybdenum atom (Mo). Therefore, the resistance-change molecular chain 31 is more likely to be bonded to tungsten than to molybdenum.

Therefore, the resistance-change molecular chain 31 is bonded to the core 24 including tungsten, but is not bonded to the side wall 25 and the wiring 22. As a result, one end of each resistance-change molecular chain 31 is bonded to the surface of the core 24 facing the wiring 22 and each resistance-change molecular chain 31 extends from the one end in a direction (Z direction) from the core 24 to the wiring 22. The length of the resistance-change molecular chain 31 is, for example, about 2 nm. However, the other end of the resistance-change molecular chain 31 does not reach the wiring 22, but is separated from the wiring 22 with a gap of, for example, about 1 nm therebetween. In addition, the resistance-change molecular chain 31 is not bonded to the side wall 25 made of molybdenum. Therefore, the resistance-change molecular chain 31 is not provided between the side wall 25 and the wiring 22.

Next, a method of manufacturing the molecular memory 1 according to the embodiment will be described.

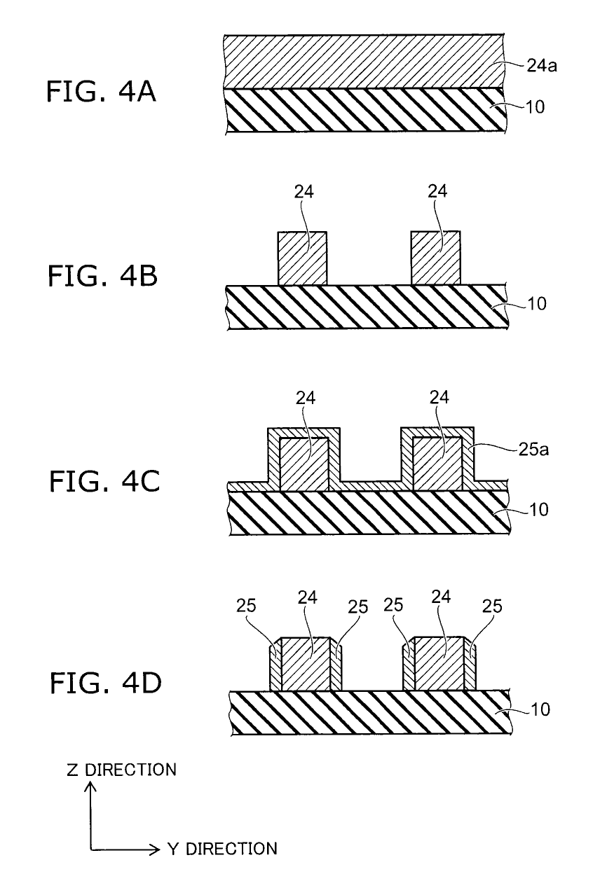

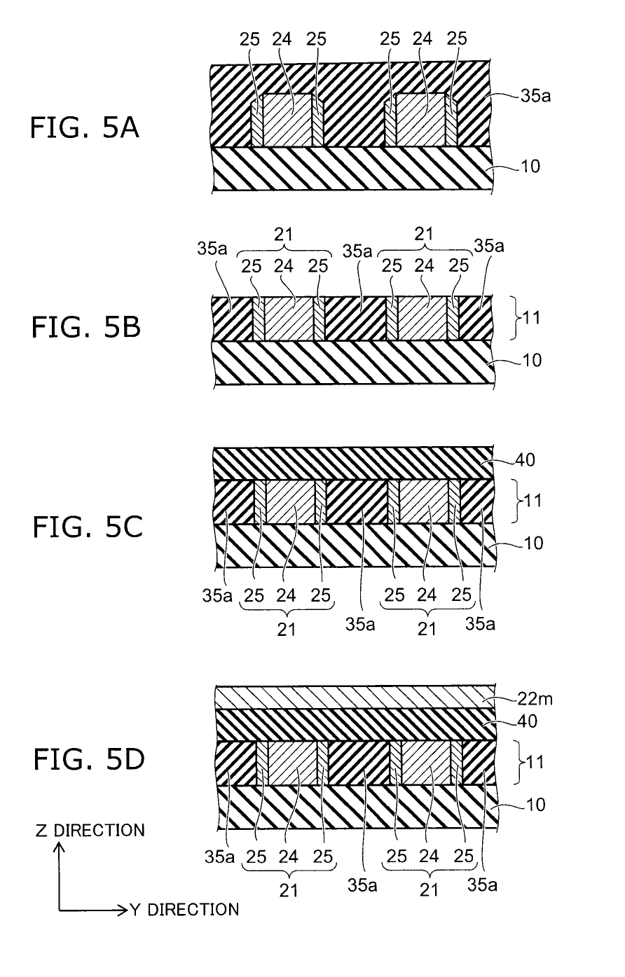

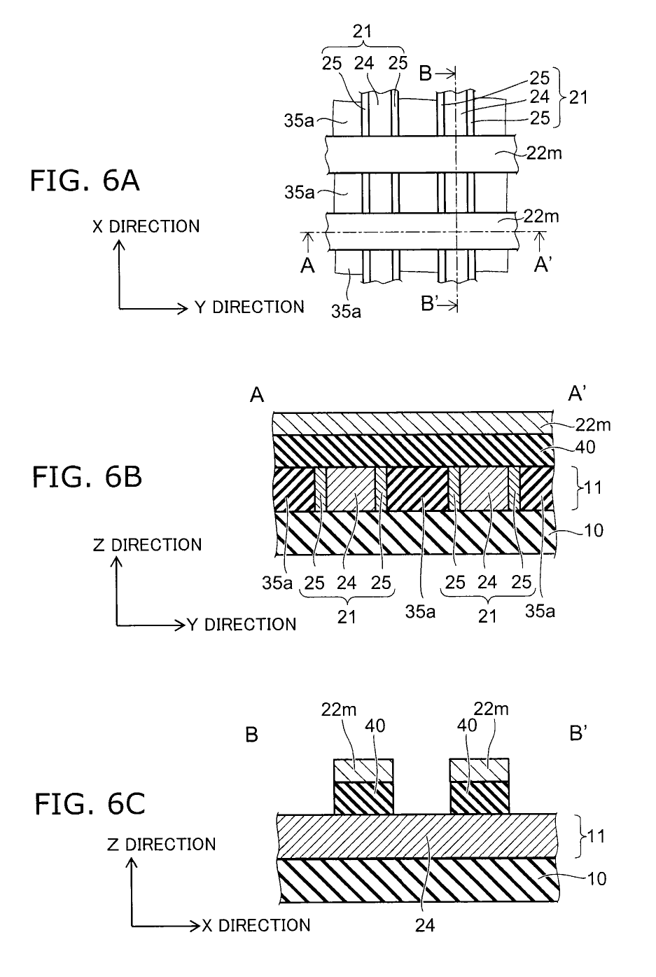

FIGS. 4A to 4D and FIGS. 5A to 5D are cross-sectional views illustrating processes of the method of manufacturing the molecular memory according to the embodiment. FIGS. 6A to 6C, FIGS. 7A to 7C, FIGS. 8A to 8C, FIGS. 9A to 9C, FIGS. 10A to 10C, FIGS. 11A to 11C, and FIGS. 12A to 12C are diagrams illustrating processes of the method of manufacturing the molecular memory according to the embodiment.

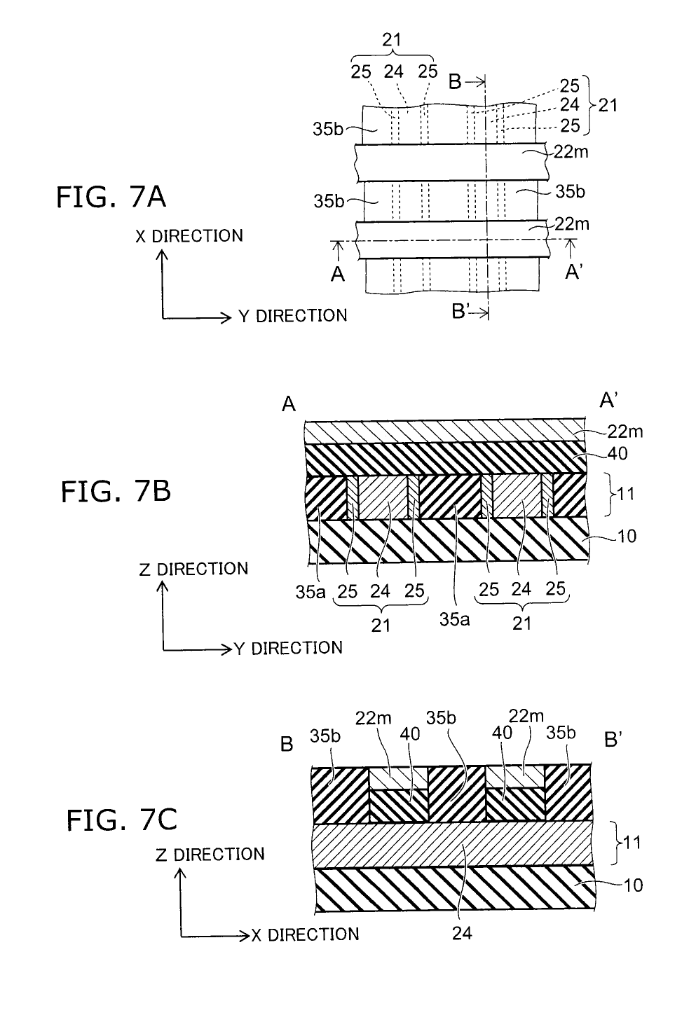

FIGS. 4A to 5D are diagrams illustrating different processes arranged in time series. FIGS. 6A to 6C show the same process. FIG. 6A is a plan view, FIG. 6B is a cross-sectional view taken along the line A-A′ of FIG. 6A, and FIG. 6C is a cross-sectional view taken along the line B-B′ of FIG. 6A. This holds for FIGS. 7A to 12C.

First, as illustrated in FIG. 4A, the interlayer insulating film 10 made of an insulating material, such as a silicon oxide or alumina, is formed on the silicon substrate (not illustrated). Then, a conductive material, for example, tungsten is deposited to form a conductive film 24a on the interlayer insulating film 10.

Then, as illustrated in FIG. 4B, the conductive film 24a is processed into lines by a lithography technique. In this way, a plurality of cores 24 extending in the X direction are formed.

Then, as illustrated in FIG. 4C, a conductive material different from tungsten, for example, molybdenum is deposited to form a conductive film 25a such that the conductive film 25a covers the core 24.

Then, as illustrated in FIG. 4D, anisotropic etching is performed to remove portions of the conductive film 25a which are arranged on the upper surface of the interlayer insulating film 10 and the upper surface of the core 24. In this case, a portion of the conductive film 25a which is arranged on the side surface of the core 24 remains. In this way, the side walls 25 are formed on both side surfaces of the core 24. In this case, an upper portion of the side wall 25 is thinner than an intermediate portion and a lower portion thereof.

Then, as illustrated in FIG. 5A, an insulating material is deposited to form an insulating film 35a on the interlayer insulating film 10 such that the insulating film 35a embeds the core 24 and the side wall 25.

Then, as illustrated in FIG. 5B, a planarizing process, such as chemical mechanical polishing (CMP), is performed using the core 24 as a stopper to planarize the upper surface of the insulating film 35a. In this case, after the core 24 is exposed, the planarizing process is performed for a predetermined period of time to remove the upper portion of the core 24 and the upper portion of the side wall 25, that is, a relatively thin portion. In this way, the side wall 25 is reliably exposed. The core 24 and the pair of side walls 25 formed on both side surfaces of the core 24 form the wiring 21. In addition, a plurality of wirings 21 and the insulating film 35a remaining therebetween form the wiring layer 11.

Then, as illustrated in FIG. 5C, a material different from the materials forming the core 24, the side wall 25, and the insulating film 35a, for example, a silicon oxide, alumina, or a silicon nitride is deposited to form a sacrificial film 40 on the wiring layer 11.

Then, as illustrated in FIG. 5D, a conductive material different from tungsten, for example, molybdenum is deposited to form a conductive film 22m on the sacrificial film 40.

Then, as illustrated in FIGS. 6A to 6C, a lithography technique is used to pattern the conductive film 22m and the sacrificial film 40. In this way, the conductive film 22m and the sacrificial film 40 are processed into a linear stacked body extending in the Y direction.

Then, as illustrated in FIGS. 7A to 7C, an insulating material different from the material forming the sacrificial film 40, for example, a silicon oxide, alumina, or a silicon nitride is deposited to form an insulating film 35b. Then, the planarizing process, such as CMP, is performed using the conductive film 22m as a stopper to planarize the upper surface of the insulating film 35b. In this way, the insulating film 35b is removed from the upper surface of the conductive film 22m and the insulating film 35b is embedded between the stacked bodies of the sacrificial film 40 and the conductive film 22m.

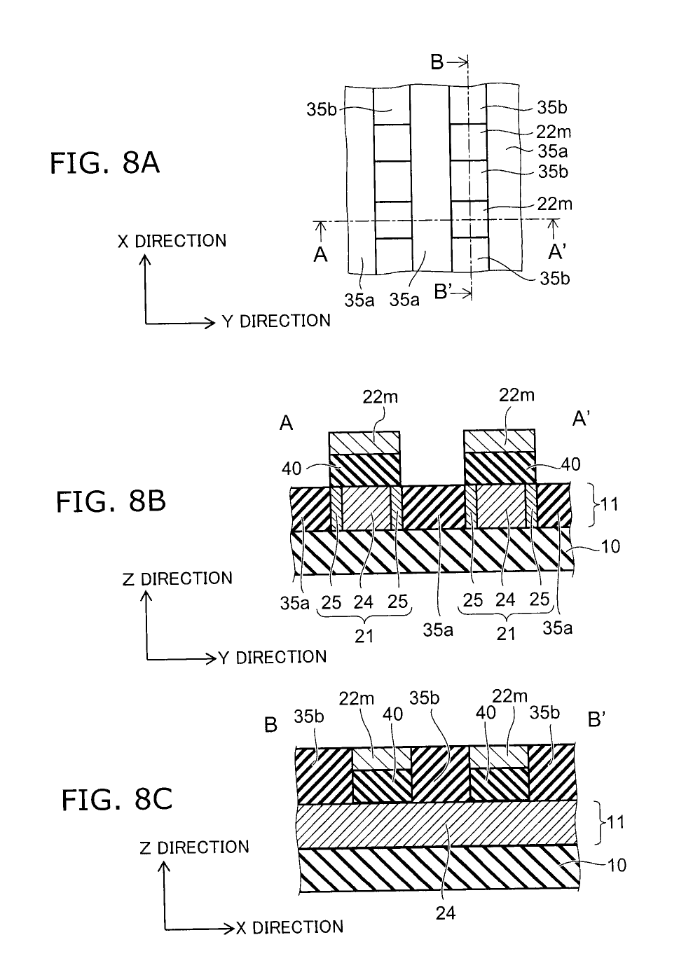

Then, as illustrated in FIGS. 8A to 8C, the lithography technique is used to process the conductive film 22m, the sacrificial film 40, and the insulating film 35b into lines extending in the X direction. In this way, the stacked bodies of the sacrificial film 40 and the conductive film 22m are divided in the X direction and the Y direction and become a plurality of island-shaped portions which are arranged in a matrix. In addition, the insulating film 35b is divided in the X direction and the Y direction and is arranged between the stacked bodies of the sacrificial film 40 and the conductive film 22m which are adjacent to each other in the X direction. That is, the stacked bodies and the insulating films 35b are alternately arranged directly below the wiring 21.

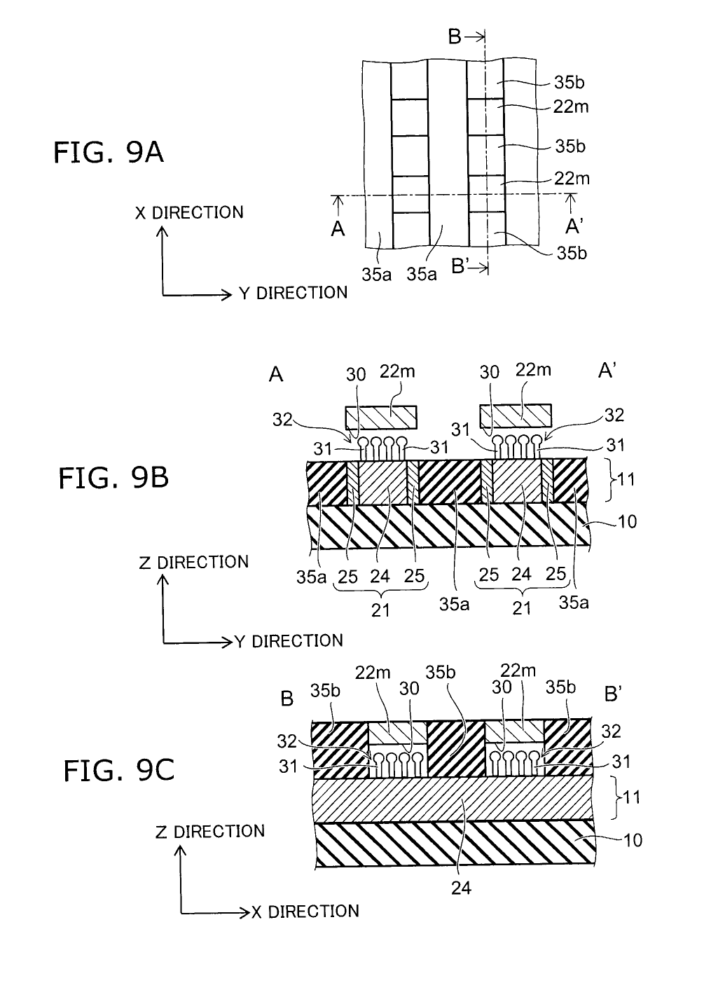

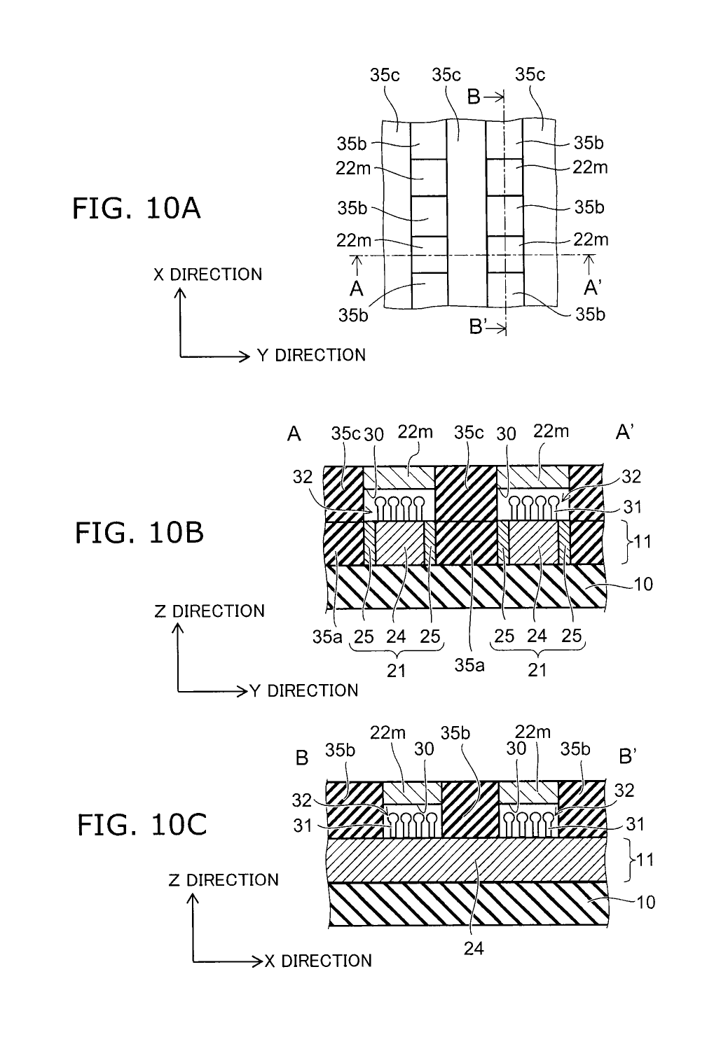

Then, as illustrated in FIGS. 9A to 9C, for example, wet etching is performed to remove the sacrificial film 40 (see FIGS. 8A and 8B). In this way, after the sacrificial film 40 is removed, the gap 30 is formed. The wiring 21 is arranged below the gap 30 and the conductive film 22m is arranged above the gap 30. The insulating films 35b are arranged on both sides of the gap 30 in the X direction and both sides of the gap 30 in the Y direction are opened.

Then, a chemical including the resistance-change molecular chain 31 (see FIG. 3) is infiltrated into the gap 30. In this way, the thiol group of the resistance-change molecular chain 31 is bonded to a tungsten atom (W) included in the core 24 of the wiring 21 and one end of the resistance-change molecular chain 31 is bonded to the core 24. The resistance-change molecular chain 31 is not bonded to the side wall 25 and the conductive film 22m made of molybdenum. Then, for example, a drying process is performed to remove a liquid in the chemical from the gap 30. As a result, the organic molecular layer 32 is formed between the closest portions of the core 24 and the conductive film 22m. Each organic molecular layer 32 includes, for example, tens to hundreds of the resistance-change molecular chains 31. In this case, since the resistance-change molecular chain 31 is not bonded to the side wall 25 and the conductive film 22m, the organic molecular layer 32 is not provided between the side wall 25 and the conductive film 22m.

Then, as illustrated in FIGS. 10A to 10C, an insulating material, such as a silicon oxide, alumina, or a silicon nitride, is deposited to form an insulating film 35c. Then, the planarizing process, such as CMP, is performed using the conductive film 22m as a stopper to planarize the upper surface of the insulating film 35c. In this way, the insulating film 35c is embedded between the stacked bodies including the gap 30, the organic molecular layer 32, and the conductive film 22m. In this case, the insulating material is hardly infiltrated into the gap 30 and the gap 30 remains. Therefore, the insulating material is not infiltrated between the resistance-change molecular chains 31 formed in the gap 30. As a result, the insulating film 35c is arranged directly above the insulating film 35a and the insulating film 35b is arranged directly above the wiring 21 between the gaps 30.

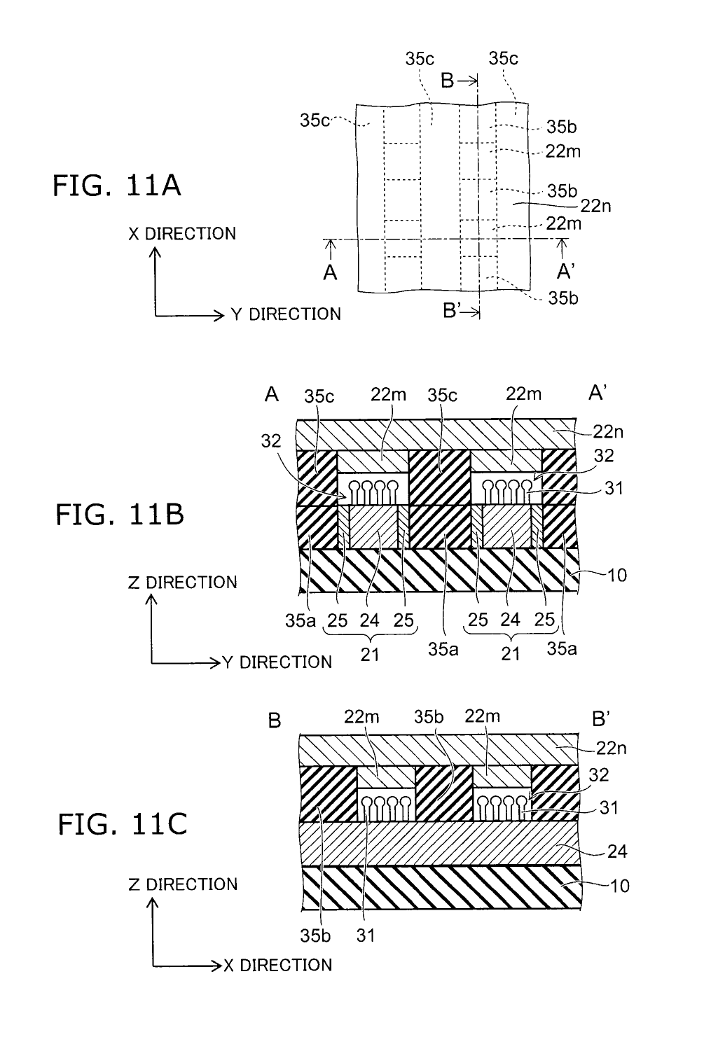

Then, as illustrated in FIGS. 11A to 11C, a conductive material different from tungsten, for example, molybdenum is deposited to form a conductive film 22n. The conductive film 22n comes into contact with the conductive film 22m.

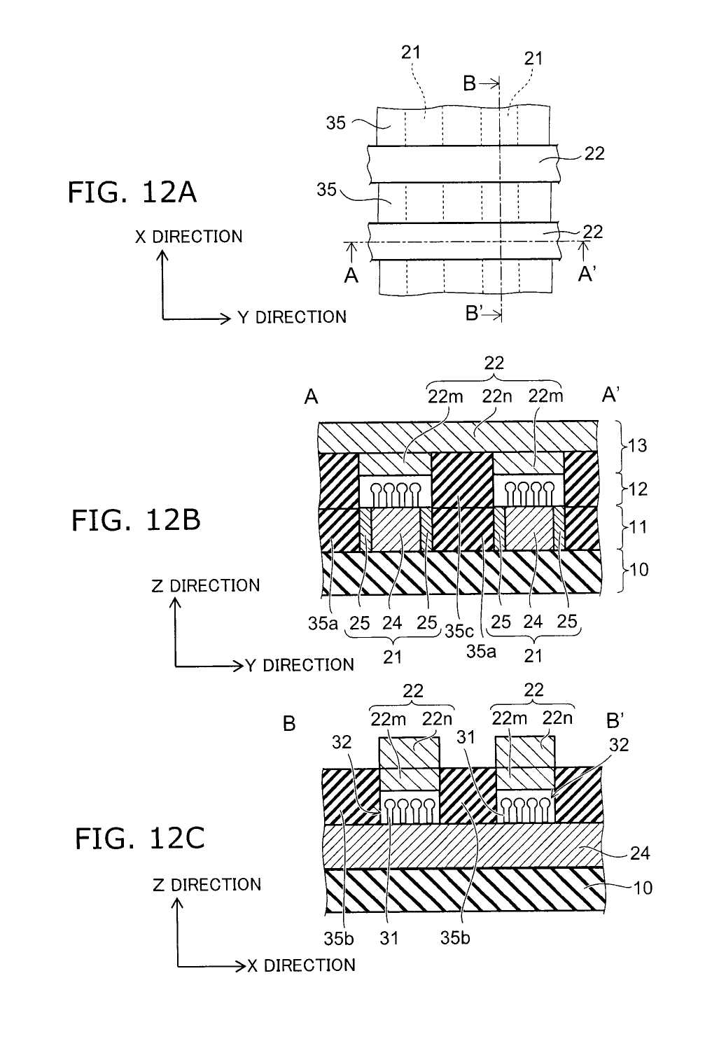

Then, as illustrated in FIGS. 12A to 12C, the lithography technique is used to process the conductive film 22n into a plurality of lines extending in the Y direction. In this case, the conductive film 22n remains so as to pass through a region directly above the conductive film 22m. Then, an insulating material (not illustrated) is deposited so as to embed the conductive film 22n. In this way, the molecular memory 1 according to the embodiment is manufactured.

In the molecular memory 1, the conductive film 22m and the conductive film 22n form the wiring 22. The conductive film 22m corresponds to the convex portion 22p of the wiring 22. The insulating films 35a to 35c and the insulating material which is deposited after the insulating films 35a to 35c are formed are a portion of the interwiring insulating film 35. In the Z direction, a region in which the wiring 22 is arranged is the wiring layer 13 and a region between the wiring layer 11 and the wiring layer 13, that is, a region in which the gap 30 and the organic molecular layer 32 are formed in the memory layer 12.

Each memory cell including one organic molecular layer 32 is formed in a space between the closest portions of the wiring 21 and the wiring 22. In this way, the memory cells are arranged in a matrix in the X direction and the Y direction. When a predetermined voltage is applied between one wiring 21 and one wiring 22, the state of electrons of the resistance-change molecular chain 31 in the organic molecular layer 32 between the wirings 21 and 22 is changed and an electrical resistance value is changed. In this way, it is possible to write information to each memory cell. In addition, the electrical resistance value between the wiring 21 and the wiring 22 is detected to read the written information.

Next, the operation and effect of the embodiment will be described.

As illustrated in FIG. 2, in the molecular memory 1 according to the embodiment, the wiring 21 includes the core 24 and the side walls 25 and the core 24 comes into contact with the side walls 25. Therefore, as a wiring for transmitting an electric signal, the core 24 and the side walls 25 integrally function as the wiring 21. When potential is applied to the wiring 21, the electric field is concentrated on the corners of the wiring 21, that is, the upper portion of the side wall 25. The core 24 and the side wall 25 are made of different conductive materials. The resistance-change molecular chain 31 is more likely to be bonded to the core 24 than to the side wall 25. Therefore, the resistance-change molecular chain 31 is arranged between the core 24 and the wiring 22, but is not arranged between the side wall 25 and the wiring 22. As such, since the resistance-change molecular chain 31 is not bonded to the side wall 25 on which the electric field is concentrated, it is possible to prevent the deterioration of the resistance-change molecular chain 31 due to the concentration of a current. As a result, it is possible to achieve a molecular memory with high reliability.

In addition, since the side wall 25 is made of a material which is less likely to be bonded to the resistance-change molecular chain 31, it is possible to form the above-mentioned structure in a self-aligned manner.

Next, a first comparative example will be described.

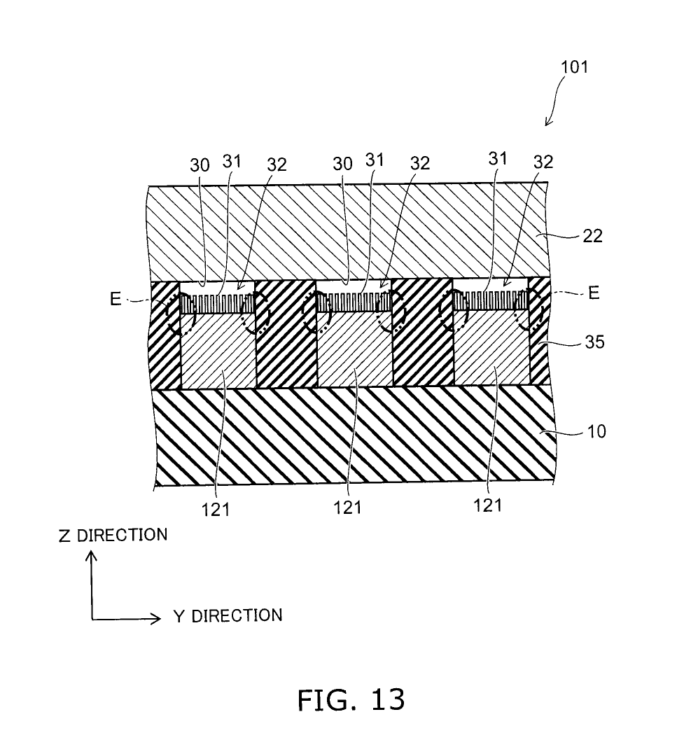

FIG. 13 is a cross-sectional view illustrating a molecular memory according to the comparative example.

As illustrated in FIG. 13, in a molecular memory 101 according to the comparative example, a wiring 121 is not divided into a core and a side wall, but is integrally formed of tungsten. A wiring 22 is integrally formed of molybdenum. Therefore, as viewed from the Z direction, resistance-change molecular chains 31 are arranged in the entire overlap region between the wiring 121 and the wiring 22.

When potential is applied to the wiring 121, the electric field applied to the edge E of the wiring 121, that is, both ends of the wirings 121 in the width direction is stronger than that applied to the center thereof in the width direction. Therefore, even when the resistance-change molecular chains 31 are uniformly formed in the width direction of the wiring 121, a current is concentrated on the resistance-change molecular chain 31 bonded to the edge E and the resistance-change molecular chain 31 is likely to deteriorate. When the resistance-change molecular chain 31 deteriorates, a defect, such as an increase in leakage current, is likely to occur. Therefore, the reliability of the molecular memory 101 is reduced.

Next, a second embodiment will be described.

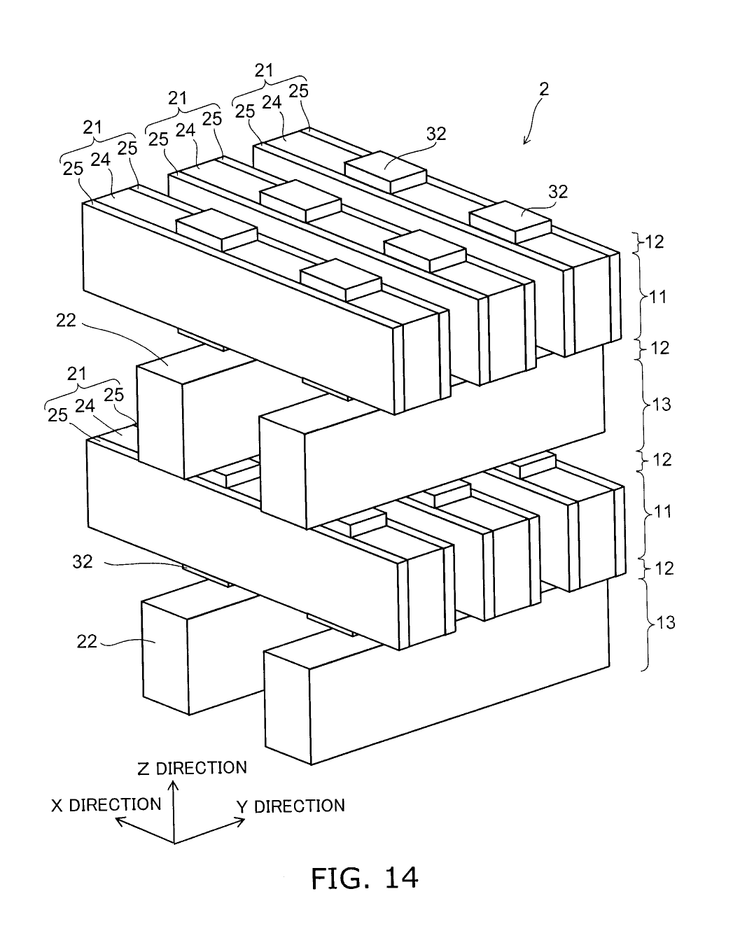

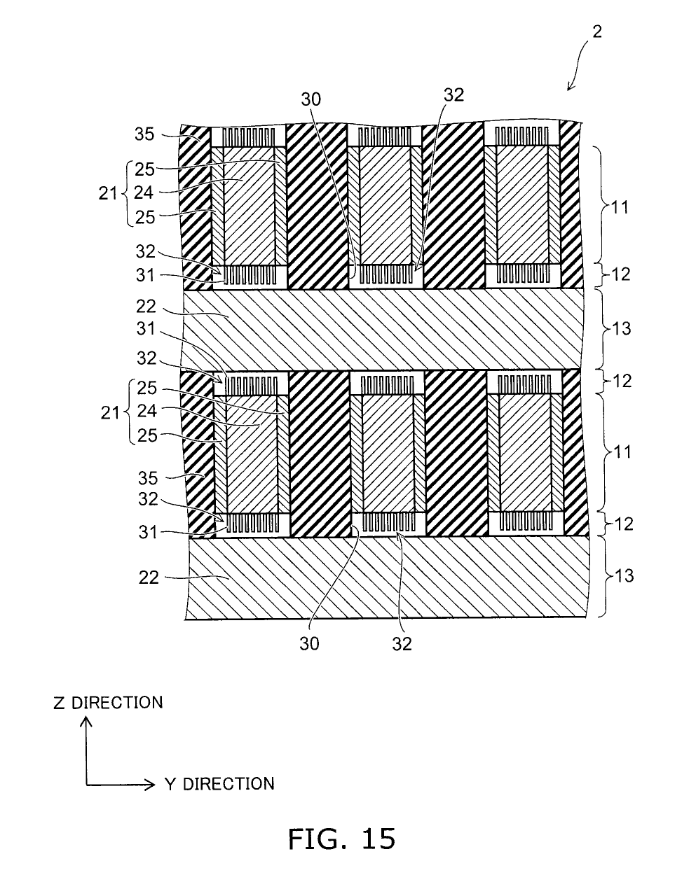

FIG. 14 is a perspective view illustrating a molecular memory according to the embodiment. FIG. 15 is a cross-sectional view illustrating the molecular memory according to the embodiment.

For ease of illustration, FIG. 14 shows only a conductive portion and does not show an insulating portion. In FIGS. 14 and 15, a convex portion 22p (see FIG. 2) of a wiring 22 is not illustrated.

As illustrated in FIGS. 14 and 15, a molecular memory 2 according to the embodiment includes a plurality of wiring layers 11, a plurality of memory layers 12, and a plurality of wiring layers 13. The wiring layers 11 and the wiring layers 13 are alternately stacked in the Z direction, with the memory layers 12 interposed between. That is, the layers are stacked in the order of the wiring layer 11, the memory layer 12, the wiring layer 13, the memory layer 12, the wiring layer 11, the memory layer 12, the wiring layer 13, . . . . The processes illustrated in FIGS. 4A to 12C may be repeatedly performed plural times to manufacture the molecular memory 2.

According to the embodiment, a plurality of wiring layers 11, a plurality of memory layers 12, and a plurality of wiring layers 13 are stacked to arrange memory cells in the Z direction. That is, the memory cells can be arranged in a three-dimensional matrix along the X direction, the Y direction, and the Z direction. As a result, it is possible to improve the degree of integration of the memory cells and increase the recording density of the molecular memory. The configurations other than the above, the operation and effect, and a manufacturing method of the embodiment are similar to those of the first embodiment.

Next, a third embodiment will be described.

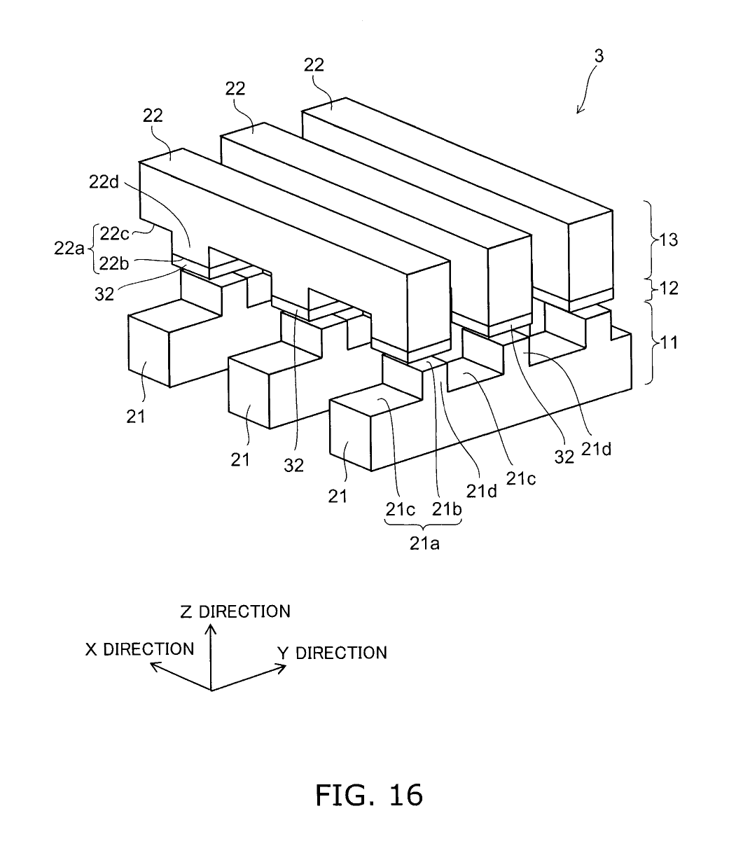

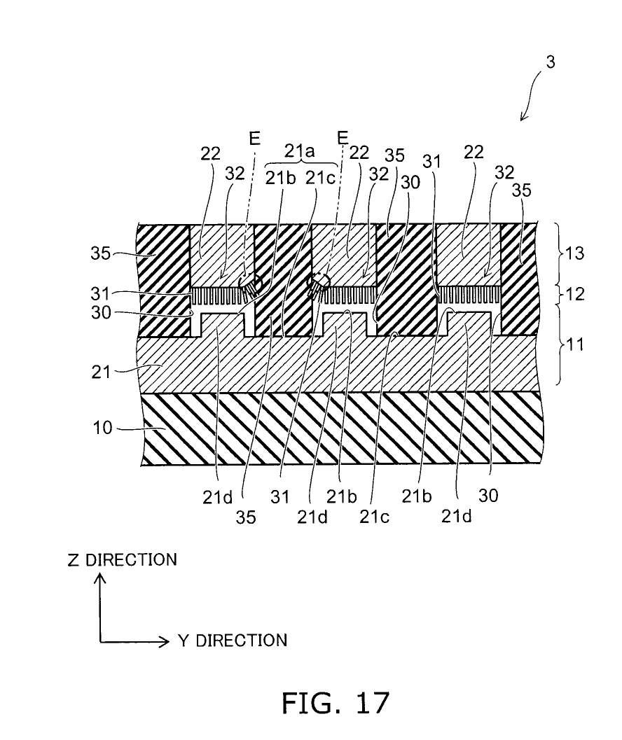

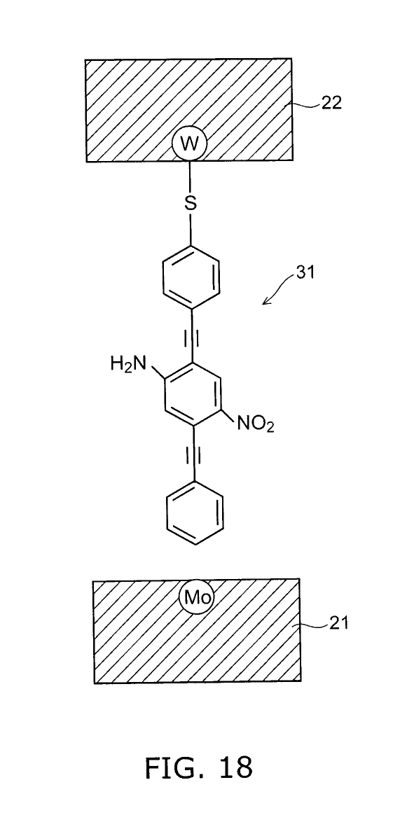

FIG. 16 is a perspective view illustrating a molecular memory according to the embodiment. FIG. 17 is a cross-sectional view illustrating the molecular memory according to the embodiment. FIG. 18 is a diagram illustrating a resistance-change molecular chain according to the embodiment.

For ease of illustrating, FIG. 16 shows only a conductive portion and does not show an insulating portion.

As illustrated in FIGS. 16 and 17, in a molecular memory 3 according to the embodiment, an interlayer insulating film 10 is provided on a silicon substrate (not illustrated) and a wiring layer 11, a memory layer 12, and a wiring layer 13 are stacked on the interlayer insulating film 10 in this order. Hereinafter, the stacked direction is referred to as a “Z direction”. In the wiring layer 11, a plurality of wirings 21 extending in one direction (hereinafter, referred to as a “Y direction”) are periodically arranged. In the wiring layer 13, a plurality of wirings 22 extending in a direction (hereinafter, referred to as an “X direction”) intersecting the Y direction, for example, in a direction perpendicular to the Y direction are periodically arranged. The X direction, the Y direction, and the Z direction are perpendicular to each other. The wiring 21 and the wiring 22 are made of different conductive materials. The wiring 21 is made of, for example, molybdenum (Mo) and the wiring 22 is made of, for example, tungsten (W).

In an upper surface 21a of the wiring 21, that is, a surface of the wiring 21 which faces the wiring 22, a region 21b facing the center of the wiring 22 in the width direction (Y direction) is closer to the wiring 22 than a region 21c which faces both ends of the wiring 22 in the width direction. The region 21c also faces a space between the wirings 22. In this way, a convex portion 21d which protrudes toward the center of the wiring 22 in the width direction is formed on the upper surface 21a of the wiring 21. The convex portions 21d are periodically arranged at the same interval as that at which the wirings 22 are arranged in the direction (Y direction) in which the wiring 21 extends. In addition, the convex portion 21d is formed over the total length of the wiring 21 in the width direction.

In a lower surface 22a of the wiring 22, that is, a surface of the wiring 22 facing the wiring 21, a region 22b facing the wiring 21 is closer to the wiring 21 than a region 22c facing a space between the wirings 21. In this way, a convex portion 22d which protrudes toward the wiring 21 is formed on the lower surface 22a of the wiring 22. The convex portions 22d are periodically arranged at the same interval as that at which the wirings 21 are arranged in the direction (X direction) in which the wiring 22 extends. In addition, the convex portion 22d is formed over the total length of the wiring 22 in the width direction.

A gap 30 is formed between the closest portions of the wiring 21 and the wiring 22, that is, directly below the convex portion 22d. In this way, in the memory layer 12, a plurality of gaps 30 are arranged in a matrix in the X direction and the Y direction. An organic molecular layer 32 including a plurality of resistance-change molecular chains 31 is formed in each gap 30. The resistance-change molecular chain 31 is a molecule whose electrical resistance value is changed when an electric signal, such as a voltage or a current, is input. Each organic molecular layer 32 includes, for example, tens to hundreds of resistance-change molecular chains 31.

As illustrated in FIG. 18, the resistance-change molecular chain 31 is, for example, 4-[2-amino-5-nitro-4-(phenylethynyl)phenylethynyl]benzenethiol and has a thiol group (R—SH) at one end. It is easy for a sulfur atom (S) of the thiol group to be bonded to a tungsten atom (W). The resistance-change molecular chain 31 does not include a group which is likely to be bonded to a molybdenum atom (Mo). Therefore, the resistance-change molecular chain 31 is more likely to be bonded to tungsten than to molybdenum.

Therefore, the resistance-change molecular chain 31 is bonded to the wiring 22 made of tungsten, but is not bonded to the wiring 21 made of molybdenum. As a result, one end of each resistance-change molecular chain 31 is bonded to the lower surface of the convex portion 22d of the wiring 22, that is, the region 22b and each resistance-change molecular chain 31 extends from the one end in a direction (Z direction) from the wiring 22 to the wiring 21. The length of the resistance-change molecular chain 31 is, for example, about 2 nm. However, the other end of the resistance-change molecular chain 31 does not reach the wiring 21, but is separated from the wiring 21 with a gap of, for example, about 1 nm therebetween.

In addition, the molecular memory 3 includes an interwiring insulating film 35 that is provided so as to embed the wiring 21, the wiring 22, and the organic molecular layer 32. The interlayer insulating film 10 and the interwiring insulating film 35 are made of, an insulating material, such as a silicon oxide, alumina, or a silicon nitride.

For example, the end of the wiring 22 in the width direction means about 10% to 30% of the width of the wiring 22. Therefore, the length of the convex portion 21d in the Y direction is about 40% to 80% of the width of the wiring 22. For example, the width of the wirings 21 and 22 is 10 nm, the length of the convex portion 21d in the Y direction is 6 nm, and the height of the convex portion 21d is in the range of 4 nm to 5 nm.

Next, a method of manufacturing the molecular memory 3 according to the embodiment will be described.

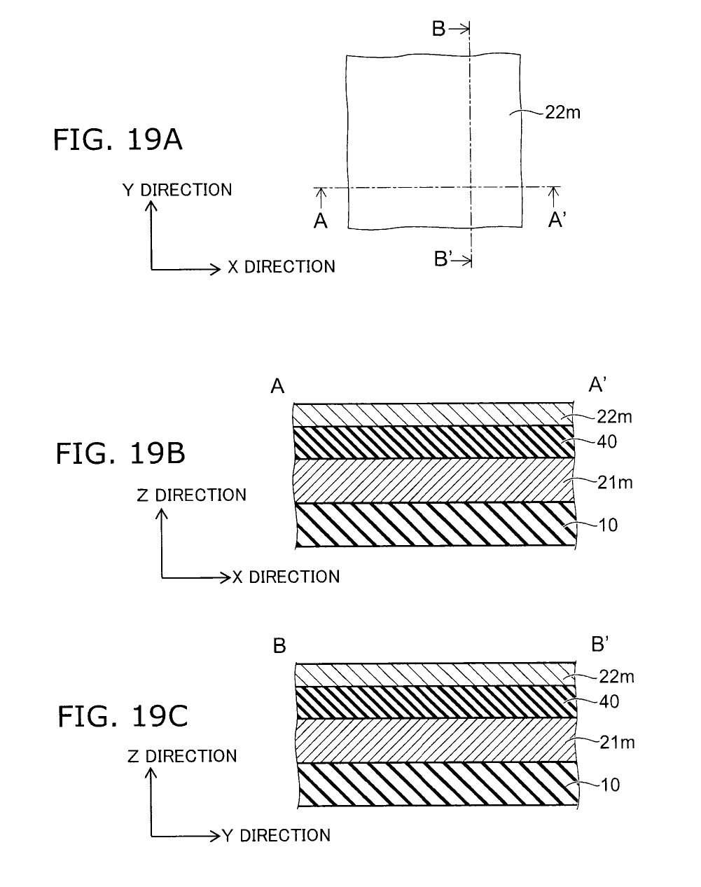

FIGS. 19A to 19C, FIGS. 20A to 20C, FIGS. 21A to 21C, FIGS. 22A to 22C, FIGS. 23A to 23C, FIGS. 24A to 24C, FIGS. 25A to 25C, and FIGS. 26A to 26C are diagrams illustrating processes of the method of manufacturing the molecular memory according to the embodiment.

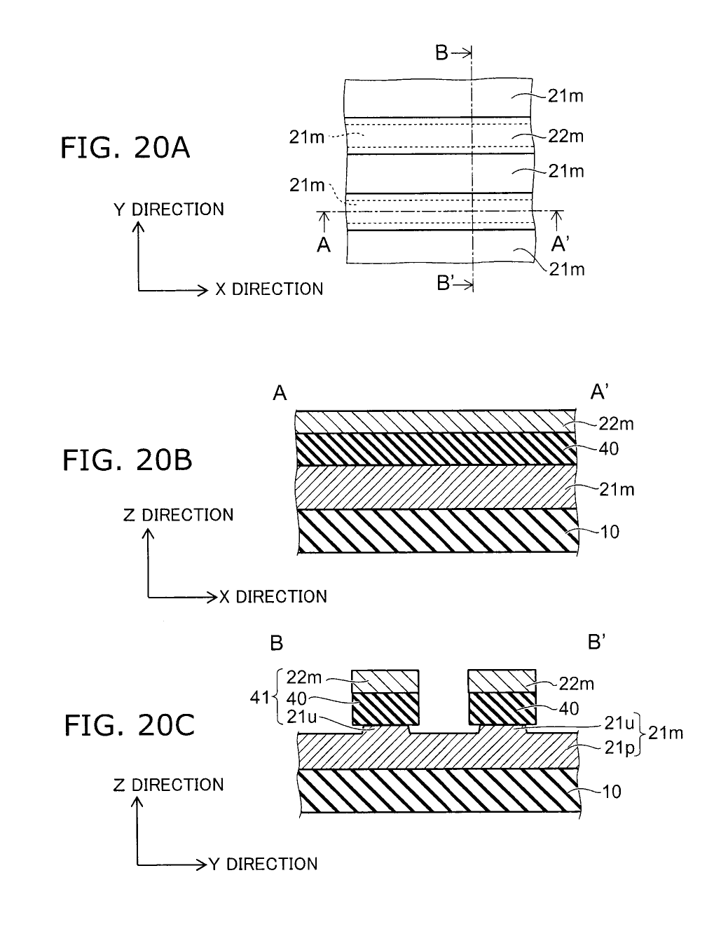

FIGS. 19A to 19C show the same process. FIG. 19A is a plan view, FIG. 19B is a cross-sectional view taken along the line A-A′ of FIG. 19A, and FIG. 19C is a cross-sectional view taken along the line B-B′ of FIG. 19A. This holds for FIGS. 20A to 26C.

First, as illustrated in FIGS. 19A to 19C, the interlayer insulating film 10 made of an insulating material, such as a silicon oxide or alumina, is formed on the silicon substrate (not illustrated). Then, a conductive material, for example, molybdenum is deposited to form a conductive film 21m on the interlayer insulating film 10. Then, a material which will be removed by wet etching in the subsequent process, for example, a silicon oxide, aluminum oxide, or a silicon nitride is deposited to form a sacrificial film 40. Then, a conductive material different from molybdenum, for example, tungsten is deposited to form a conductive film 22m. In this way, the interlayer insulating film 10, the conductive film 21m, the sacrificial film 40, and the conductive film 22m are stacked on the silicon substrate in this order from the lower side, thereby forming a stacked body.

Then, as illustrated in FIGS. 20A to 20C, a lithography technique and an anisotropic etching technique are used to selectively remove the conductive film 22m and the sacrificial film 40, thereby forming lines extending in the X direction. Then, an upper portion 21u of the conductive film 21m is selectively removed to form lines extending in the X direction. In this way, the upper portion 21u of the conductive film 21m, the sacrificial film 40, and the conductive film 22m are stacked in this order to form a plurality of stacked bodies 41 extending in the X direction. A portion of the conductive film 21m other than the upper portion 21u, that is, a portion which is not processed into lines, but remains flat is a planer portion 21p.

Then, for example, isotropic etching is performed to etch the side of the upper portion 21u. In this way, the width of the upper portion 21u is less than that of the conductive film 22m and the sacrificial film 40. In this case, in some cases, the end of the conductive film 22m is etched a little and is damaged. For example, in some cases, the lower surface of both ends of the conductive film 22 in the width direction (Y direction) is inclined. However, the damage is not illustrated.

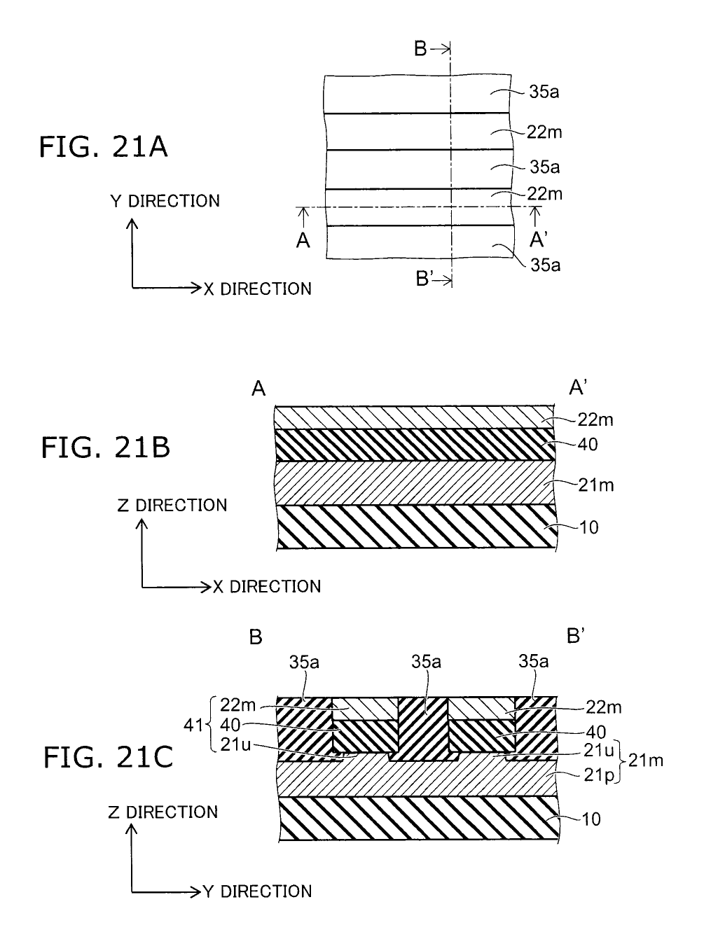

Then, as illustrated in FIGS. 21A to 21C, an insulating material different from the material forming the sacrificial film 40, for example, a silicon oxide, an aluminum oxide, or a silicon nitride is deposited to form an insulating film 35a on the planer portion 21p of the conductive film 21m such that the insulating film 35a embeds the stacked body 41. Then, a planarizing process, such as chemical mechanical polishing (CMP), is performed using the conductive film 22m as a stopper to planarize the upper surface of the insulating film 35a.

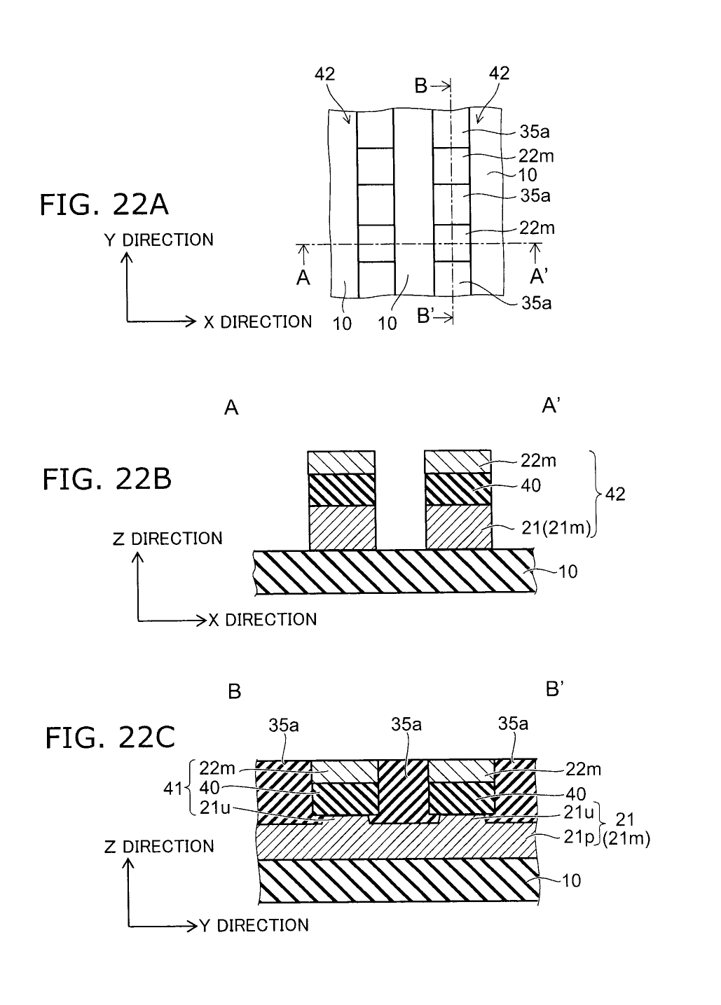

Then, as illustrated in FIGS. 22A to 22C, the lithography technique and the anisotropic etching technique are used to selectively remove the conductive film 22m, the sacrificial film 40, and the conductive film 21m. In this way, a plurality of stacked bodies 42 each of which includes the conductive film 21m, the sacrificial film 40, the conductive film 22m, and the insulating film 35a and extends in the Y direction are formed. In this case, the stacked bodies 41 each including the upper portion 21u of the conductive film 21m, the sacrificial film 40, and the conductive film 22 are divided in the X direction and the Y direction and become a plurality of island-shaped portions which are arranged in a matrix. In addition, the insulating film 35a is divided in the X direction and the Y direction and is arranged between the stacked bodies 41 which are adjacent to each other in the Y direction. The planer portion 21p of the conductive film 21m is divided into a plurality of lines extending in the Y direction. In this way, the conductive film 21m is divided into a plurality of wirings 21. That is, in each stacked body 42, the wiring 21 is provided at the lower part of the stacked body 42 and the stacked bodies 41 and the insulating films 35a are alternately arranged on the wiring 21 along the Y direction.

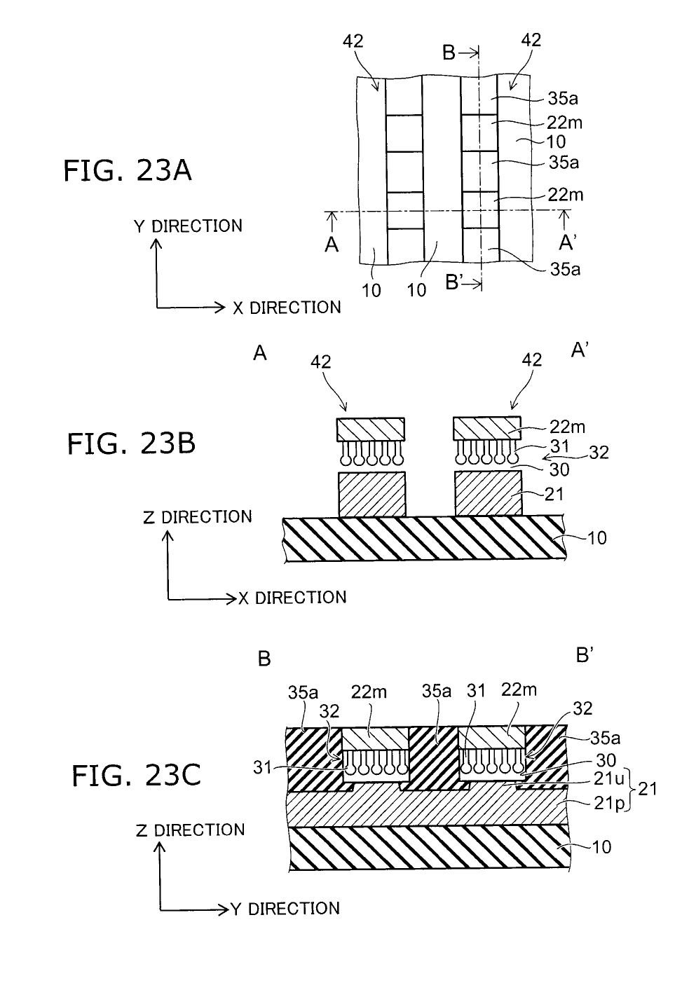

Then, as illustrated in FIGS. 23A to 23C, for example, wet etching is performed to remove the sacrificial film 40 (see FIGS. 22B and 22C). In this way, the gap 30 is formed in a space from which the sacrificial film 40 is removed. The wiring 21 is arranged below the gap 30 and the conductive film 22m is arranged above the gap 30. The insulating films 35a are arranged on both sides of the gap 30 in the Y direction and both sides of the gap in the X direction are opened.

Then, a chemical including the resistance-change molecular chain 31 (see FIG. 18) is infiltrated into the gap 30. In this way, the resistance-change molecular chain 31 is arranged in the gap 30. Since the thiol group of the resistance-change molecular chain 31 is bonded to a tungsten atom (W) included in the conductive film 22m, one end of the resistance-change molecular chain 31 is bonded to the lower surface of the conductive film 22m. The resistance-change molecular chain 31 is not bonded to the wiring 21 made of molybdenum. Then, for example, a drying process is performed to remove a liquid in the chemical from the gap 30. As a result, the organic molecular layer 32 is formed between the closest portions of each wiring 21 and each conductive film 22m. Each organic molecular layer 32 includes, for example, tens to hundreds of the resistance-change molecular chains 31.

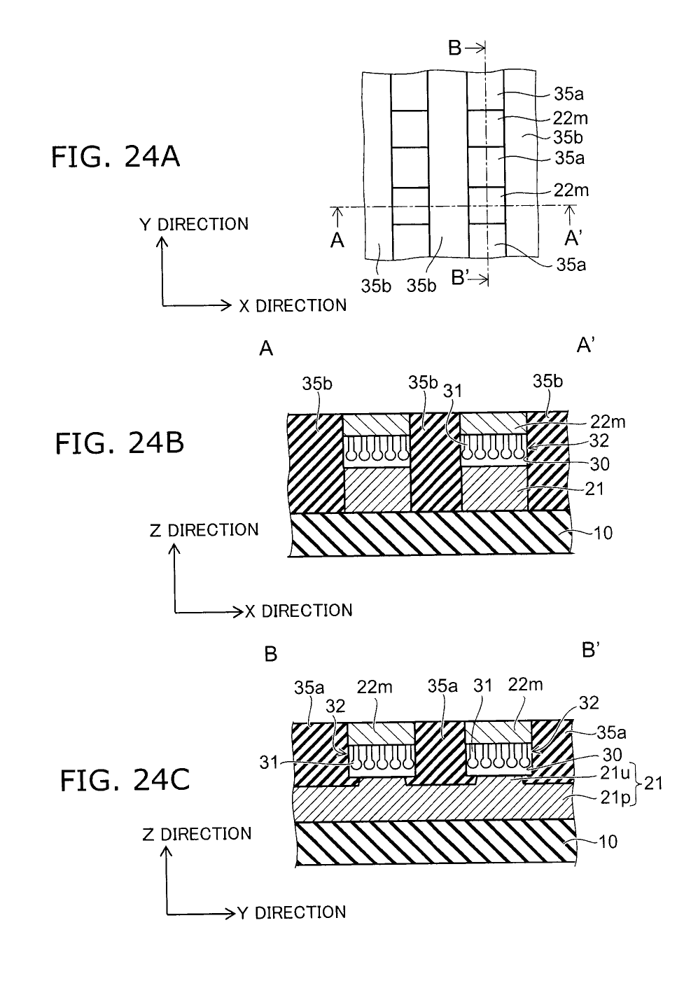

Then, as illustrated in FIGS. 24A to 24C, an insulating material, such as a silicon oxide, alumina, or a silicon nitride, is deposited to form an insulating film 35b. Then, the planarizing process, such as CMP, is performed using the conductive film 22m as a stopper to planarize the upper surface of the insulating film 35b. In this way, the insulating film 35b is removed from the upper surface of the conductive film 22m and is embedded between the stacked bodies 42. In this case, the insulating material is hardly infiltrated into the gap 30 and the gap 30 remains. Therefore, the insulating material is not infiltrated between the resistance-change molecular chains 31 formed in the gap 30.

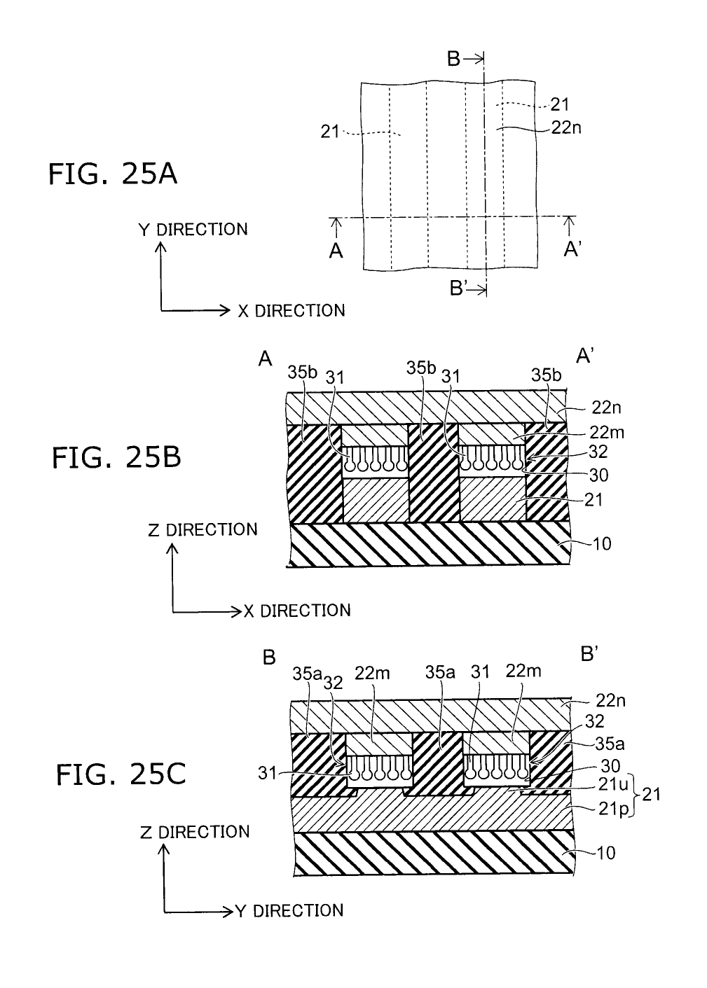

Then, as illustrated in FIGS. 25A to 25C, for example, molybdenum is deposited to form a conductive film 22n on the entire surface. The conductive film 22n comes into contact with the conductive film 22m.

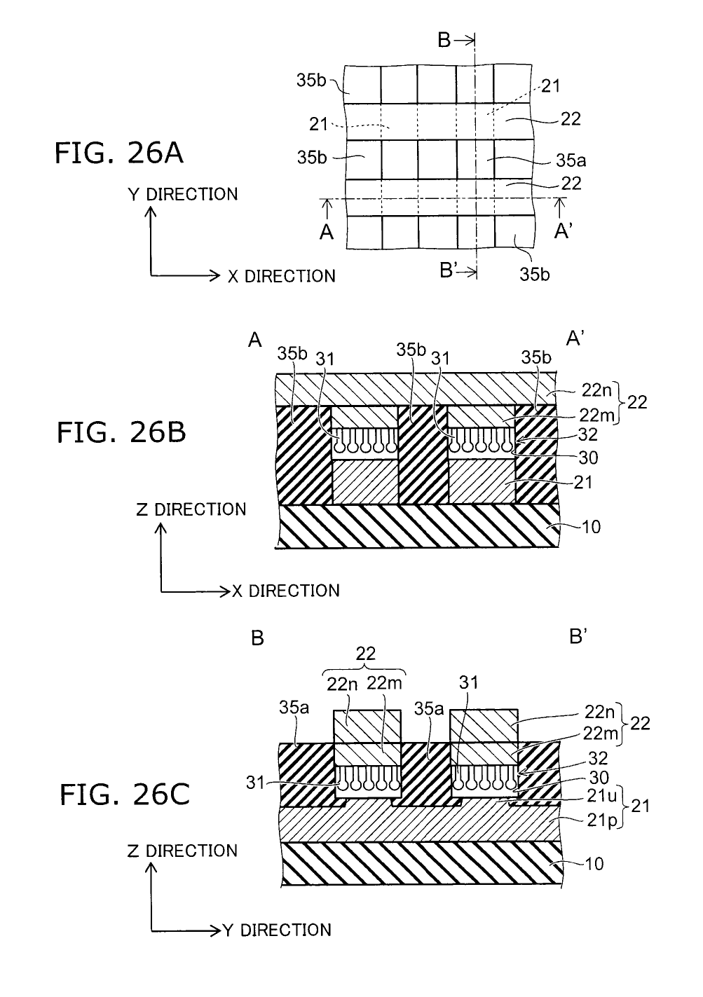

Then, as illustrated in FIGS. 26A to 26C, the lithography technique and the etching technique are used to selectively remove the conductive film 22n. In this way, the conductive film 22n is processed into a plurality of lines extending in the X direction. In this case, the conductive film 22n remains so as to pass through a region which is directly above the conductive film 22m. In this way, the conductive film 22n is commonly connected to the conductive films 22m which are arranged in a line in the X direction. Then, an insulating material (not illustrated) is deposited so as to embed the conductive film 22n which is processed into lines. In this way, the molecular memory 3 according to the embodiment is manufactured.

In the molecular memory 3, the conductive film 22m and the conductive film 22n form the wiring 22 extending in the X direction. In this case, the conductive film 22m is the convex portion 22d of the wiring 22. The upper portion 21u of the conductive film 21m is the convex portion 21d of the wiring 21. The insulating films 35a and 35b and the insulating material which is deposited thereafter are a portion of the interwiring insulating film 35. In the Z direction, a region in which the wiring 21 is arranged is the wiring layer 11, a region in which the wiring 22 is arranged is the wiring layer 13, and a region between the wiring layer 11 and the wiring layer 13, that is, a region in which the gap 30 and the organic molecular layer 32 are formed is the memory layer 12.

Each memory cell including one organic molecular layer 32 is formed in a space between the closest portions of the wiring 21 and the wiring 22. In this way, the memory cells are arranged in a matrix in the X direction and the Y direction. When a predetermined voltage is applied between one wiring 21 and one wiring 22, the state of electrons of the resistance-change molecular chain 31 in the organic molecular layer 32 between the wirings 21 and 22 is changed and an electrical resistance value is changed. In this way, it is possible to write information to each memory cell. In addition, the electrical resistance value between the wiring 21 and the wiring 22 is detected to read the written information.

Next, the operation and effect of the embodiment will be described.

As illustrated in FIG. 17, in the molecular memory 3 according to the embodiment, in the upper surface 21a of the wiring 21, the region 21b which faces the center of the wiring 22 in the width direction (Y direction) is closer to the wiring 22 than the region 22c which faces both ends of the wiring 22 in the width direction. In this way, the distance between the wiring 21 and both ends of the wiring 22 in the width direction is more than that between the wiring 21 and the center of the wiring 22 in the width direction. Therefore, among the resistance-change molecular chains 31 bonded to the lower surface 22a of the wiring 22, only the resistance-change molecular chain 31 bonded to the center of the wiring 22 in the width direction effectively functions as a storage element and the resistance-change molecular chains 31 bonded to both ends of the wiring 22 in the width direction do not function as the storage element. That is, since the distance of both ends of the wiring 22 in the width direction from the wiring 21 is long, the resistance-change molecular chains 31 bonded to both ends of the wiring 22 do not electrically interact with the wiring 21 and do not contribute to the operation of the memory cell. As a result, for example, even when there is a variation in the shape of the end of the wiring 22 in the width direction due process factors, the characteristics of the memory cell are less likely to be affected by the variation. For example, even when the edge E of the wiring 22 is damaged and the lower surface of the wiring 22 is inclined with respect to the XY plane as illustrated in FIG. 17, the switching characteristics of the memory cell are less likely to vary due to the damage of the edge E.

Next, a second comparative example will be described.

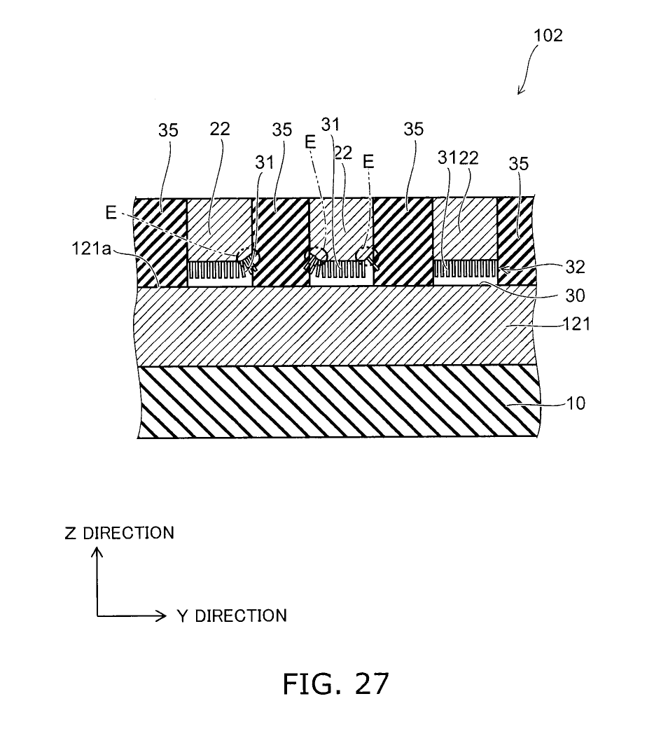

FIG. 27 is a cross-sectional view illustrating a molecular memory according to the comparative example.

As illustrated in FIG. 27, in a molecular memory 102 according to the comparative example, an upper surface 121a of a wiring 121 is flat. Therefore, the distance between the wiring 22 and a region of the upper surface 121a which faces the center of the wiring 22 in the width direction is substantially equal to the distance between the wiring 22 and a region of the upper surface 121a which faces both ends of the wiring 22 in the width direction. Therefore, for example, when a variation in the shape of the end of the wiring 22 in the width direction occurs due to process factors, a variation in the operation of the resistance-change molecular chain 31 occurs due to the variation in the shape, which results in a variation in the switching characteristics of the memory cell.

For example, when the edge E of the wiring 22 is damaged and the lower surface of the wiring 22 is inclined, the gap between the wiring 121 and the resistance-change molecular chain 31 bonded to the lower surface increases and the operation characteristics of the resistance-change molecular chain 31 are different from the operation characteristics of another resistance-change molecular chain 31. Since the variation in the shape of the end of the wiring 22 in the width direction is different for each memory cell, the switching characteristics of the memory cell vary. In particular, when the size of the memory cell is reduced, the percentage of the end in the wiring 22 increases. Therefore, a variation in the switching characteristics increases.

Next, a fourth embodiment will be described.

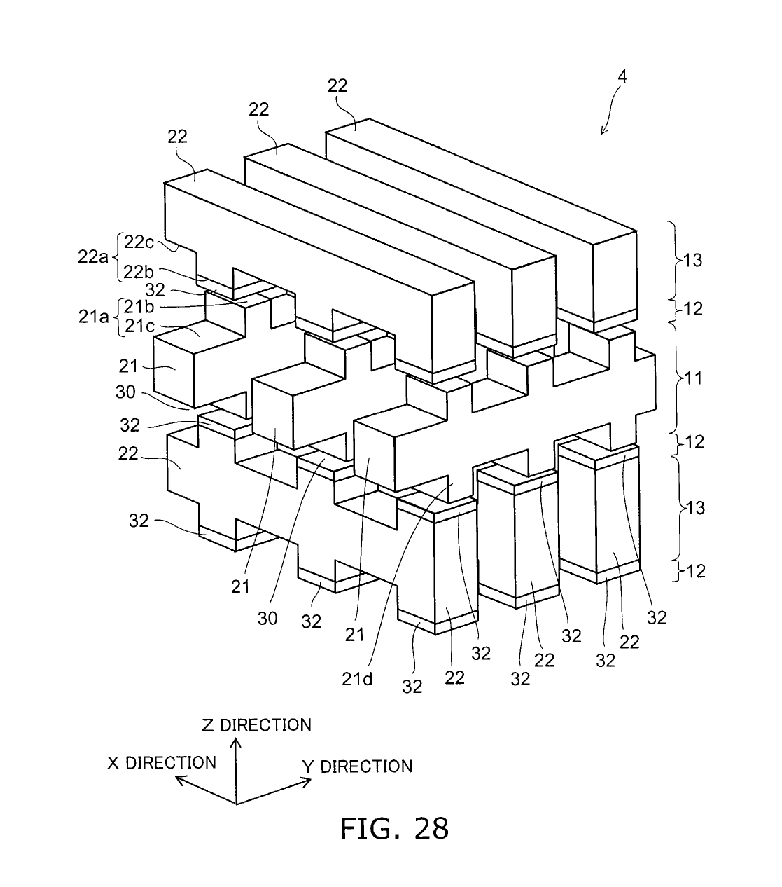

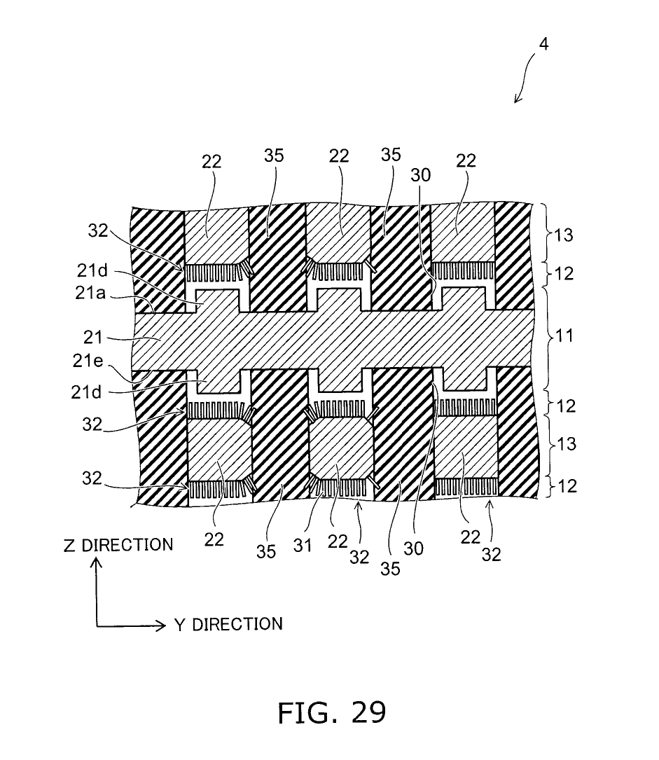

FIG. 28 is a perspective view illustrating a molecular memory according to the embodiment. FIG. 29 is a cross-sectional view illustrating the molecular memory according to the embodiment.

For ease of illustration, FIG. 28 shows only a conductive portion and does not show an insulating portion.

As illustrated in FIGS. 28 and 29, in a molecular memory 4 according to the embodiment, a plurality of wiring layers 11, a plurality of memory layers 12, and a plurality of wiring layers 13 are provided. The wiring layers 11 and the wiring layers 13 are alternately stacked in the Z direction, with the memory layers 12 interposed between. That is, the layers are stacked in the order of the wiring layer 11, the memory layer 12, the wiring layer 13, the memory layer 12, the wiring layer 11, the memory layer 12, the wiring layer 13, . . . . Convex portions 21d are formed on both an upper surface 21a and a lower surface 21e of the wiring 21. In this way, in the lower surface 21e of the wiring 21, a region which faces the center of the wiring 22 in the width direction (X direction) is lower than a region which faces both ends of the wiring 22 in the width direction.

The convex portion 21d on the lower surface 21e of the wiring 21 may be formed by the same method as that used to form the convex portion 22d on the lower surface 22a of the wiring 22. However, when the wiring 21 is formed, the width of the conductive film 22m which is processed into lines in a process corresponding to the process illustrated in FIGS. 20A to 20C is less than that of the conductive film 22n which is processed into lines in a process corresponding to the process illustrated in FIGS. 26A to 26C. In this way, it is possible to form the convex portion 21d with a length less than the width of the wiring 22 in the X direction.

According to the embodiment, since a plurality of wiring layers 11, a plurality of memory layers 12, and a plurality of wiring layers 13 are stacked, it is possible to arrange the memory cells in the Z direction. That is, the memory cells can be arranged in a three-dimensional matrix along the X direction, the Y direction, and the Z direction. As a result, it is possible to improve the degree of integration of the memory cells and increase the recording density of the molecular memory. The configurations other than the above, a manufacturing method, and the operation and effect of the embodiment are similar to those according to the third embodiment.

Next, a fifth embodiment will be described.

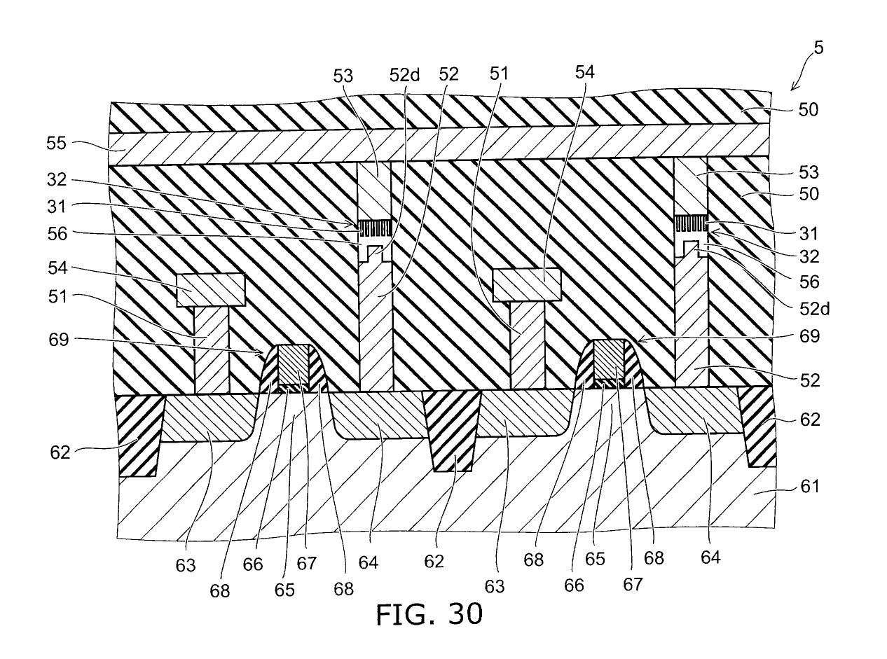

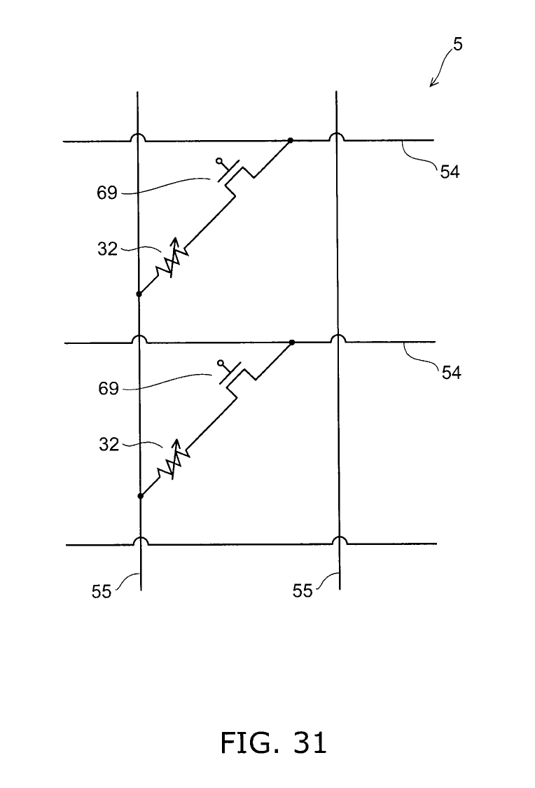

FIG. 30 is a cross-sectional view illustrating a molecular memory according to the embodiment. FIG. 31 is a circuit diagram illustrating the molecular memory according to the embodiment.

As illustrated in FIG. 30, in a molecular memory 5 according to the embodiment, an element isolation insulator 62 is selectively formed in an upper portion of a silicon substrate 61, and a source region 63 and a drain region 64 are separately formed in regions partitioned by the element isolation insulator 62. A gate insulating film 66 is provided immediately above a channel region 65 which is provided between the source region 63 and the drain region 64 on the silicon substrate 61, and a gate electrode 67 is provided on the gate insulating film 66. Side walls 68 are provided on the sides of the gate electrode 67. In this way, a field effect transistor 69 is formed.

An interlayer insulating film 50 is provided on the silicon substrate 61. A contact 51, a contact 52, a contact 53, a word line 54, and a bit line 55 are provided in the interlayer insulating film 50. The contact 52 is made of molybdenum and the contact 53 is mode of tungsten. A gap 56 is formed between the contact 52 and the contact 53 in the element separation insulating film 50.

The contact 51 is connected between the source region 63 and the word line 64. The lower end of the contact 52 is connected to the drain region 64 and the upper end thereof is exposed to the gap 56. A convex portion 52d is formed at the center of the upper end surface of the contact 52. The contact 53 is disposed immediately above the contact 52 and is separated from the contact 52 with the gap 56 interposed between. The lower end of the contact 53 is exposed to the gap 56 and the upper end thereof is connected to the bit line 55. A resistance-change molecular chain 31 is provided in the gap and is bonded to the contact 53. A plurality of resistance-change molecular chains 31 form an organic molecular layer 32.

In this way, as illustrated in FIG. 31, in the molecular memory 5, a one-resistor-one-transistor (1R1T) memory cell in which the organic molecular layer 32 serving as a storage element is connected in series to the field effect transistor 69 serving as a selection element is formed between the word line 54 and the bit line 55. The operation and effect of the embodiment are the same as those of the third embodiment.

Next, a sixth embodiment will be described.

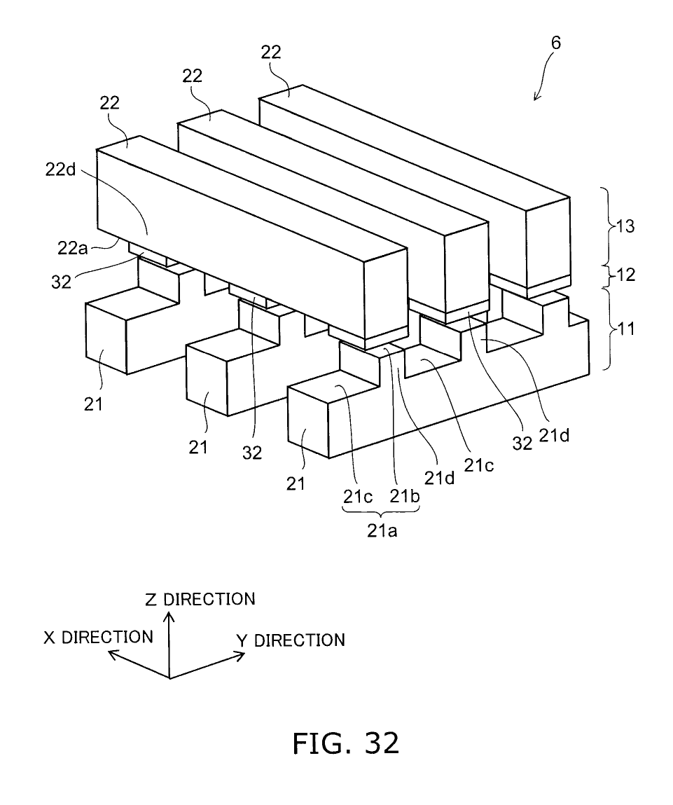

FIG. 32 is a perspective view illustrating a molecular memory according to the embodiment.

For ease of illustration, FIG. 32 shows only a conductive portion, but does not show an insulating portion.

As illustrated in FIG. 32, in a molecular memory 6 according to the embodiment, a convex portion 22d (see FIG. 16) is not formed in a wiring 22. Therefore, a lower surface 22a of the wiring 22 is flat.

The configurations other than the above and the operation and effect of the embodiment are the same as those of the third embodiment.

Next, modifications of the materials in each of the above-described embodiments will be described.

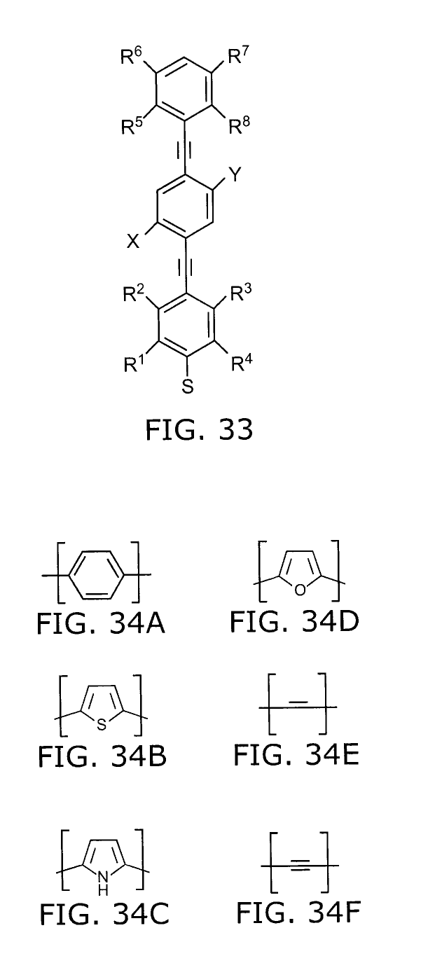

FIG. 33 is a diagram illustrating a general formula of a resistance-change molecular chain according to a modification. FIGS. 34A to 34F are diagrams illustrating molecular units capable of forming a molecule in which a π-conjugated system extends in a one-dimensional direction.

In each of the above-described embodiments, the resistance-change molecular chain 31 is 4-[2-amino-5-nitro-4-(phenylethynyl)phenylethynyl]benzenethiol illustrated in FIG. 18, but the invention is not limited thereto. For example, the resistance-change molecular chain 31 may be a molecule with variable resistance. For example, the resistance-change molecular chain 31 may be a derivative of 4-[2-amino-5-nitro-4-(phenylethynyl)phenylethynyl]benzenethiol, which is represented by a general formula illustrated in FIG. 33.

In the general formula illustrated in FIG. 33, a combination of X and Y is a combination of two of fluorine (F), chlorine (Cl), bromine (Br), iodine (I), a cyano group (CN), a nitro group (NO₂), an amino group (NH₂), a hydroxyl group (OH), a carbonyl group (CO), and a carboxyl group (COOH). In addition, Rn (n=1 to 8) is an arbitrary atom except for an atom in which a peripheral electron is a d electron or an f electron or a characteristic group, for example, any one of hydrogen (H), fluorine (F), chlorine (Cl), bromine (Br), iodine (I), and a methyl group (CH₃).

The resistance-change molecular chain 31 may be a molecule in which the π-conjugated system extends in a one-dimensional direction and which has a structure other than the molecular structure represented by the general formula illustrated in FIG. 33. For example, a paraphenylene derivative, an oligothiophene derivative, an oligopyrrole derivative, an oligofuran derivative, or a paraphenylene vinylene derivative may be used.

The molecular unit capable of forming the molecule in which the π-conjugated system extends in a one-dimensional direction may be paraphenylene illustrated in FIG. 34A, thiophene illustrated in FIG. 34B, pyrrole illustrated in FIG. 34C, furan illustrated in FIG. 34D, vinylene illustrated in FIG. 34E, or alkyne illustrated in FIG. 34F. In addition, a six-membered heterocyclic compound, such as pyridine, may be used.

When the length of the π-conjugated system is short, an electron injected from the electrode passes without remaining on the molecule. Therefore, it is preferable that the length of the π-conjugated system be greater than a predetermined value in order to store charge. It is desirable that the length of the π-conjugated system be equal to or greater than 5 in the unit of —CH═CH— in one-dimensional direction. In the case of a benzene ring (paraphenylene), this corresponds to 3 or more. The diameter of the benzene ring is about two times more than the width of polaron, which is a carrier of the π-conjugated system. On the other hand, when the length of the π-conjugated system is long, for example, a voltage drop occurs due to charge conduction in the molecule. Therefore, it is preferable that the length of the π-conjugated system be equal to or less than 20 in the unit of —CH═CH— in one-dimensional direction. In the case of a benzene ring, this corresponds to 10 or less.

The materials forming each wiring, the core, and the side wall are not limited to those according to each of the above-described embodiments. Preferred conductive materials forming each wiring, the core, and the side wall vary depending on the molecular structure of one end of the resistance-change molecular chain 31.

For example, as illustrated in FIGS. 3 and 18, when one end of the resistance-change molecular chain 31 is a thiol group, it is preferable that a material forming a portion which is desired to be chemically bonded to the resistance-change molecular chain 31 be gold (Au), silver (Ag), copper (Cu), tungsten nitride (WN), tantalum nitride (TaN), or titanium nitride (TiN), in addition to tungsten (W). Among them, in particular, it is preferable that the material be tungsten (W), gold (Au), or silver (Ag) which is likely to form chemical bonding. On the other hand, it is preferable that a material forming a portion which is not desired to be chemically bonded to the resistance-change molecular chain 31 be tantalum (Ta), molybdenum nitride (MoN), or silicon (Si), in addition to molybdenum (Mo). The side wall 25 and the wiring 22 illustrated in FIG. 3 may be made of different materials.

For example, when one end of the resistance-change molecular chain 31 is an alcohol group or a carboxyl group, it is preferable that the material forming the portion which is desired to be chemically bonded to the resistance-change molecular chain 31 be tungsten (W), tungsten nitride (WN), tantalum (Ta), tantalum nitride (TaN), molybdenum (Mo), molybdenum nitride (MoN), or titanium nitride (TiN). Among them, in particular, it is preferable that the material be tantalum (Ta), tantalum nitride (TaN), molybdenum nitride (MoN), or titanium nitride (TiN) which is likely to form chemical bonding. On the other hand, it is preferable that the material forming the portion which is not desired to be chemically bonded to the resistance-change molecular chain 31 be gold (Au), silver (Ag), copper (Cu), or silicon (Si).

For example, when one end of the resistance-change molecular chain 31 is a silanol group, it is preferable that the material forming the portion which is desired to be chemically bonded to the resistance-change molecular chain 31 be silicon (Si) or metal oxide. On the other hand, it is preferable that the material forming the portion which is not desired to be chemically bonded to the resistance-change molecular chain 31 be gold (Au), silver (Ag), copper (Cu), tungsten (W), tungsten nitride (WN), tantalum (Ta), tantalum nitride (TaN), molybdenum (Mo), molybdenum nitride (MoN), or titanium nitride (TiN). When the material forming the wiring is compound, the composition of the compound may be appropriately selected. In addition, the wiring may be made of, for example, graphene or carbon nanotube.

According to the above-described embodiments, it is possible to achieve a molecular memory with high reliability and a method of manufacturing the molecular memory.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A molecular memory comprising:
a first electrode;
a second electrode; and
a resistance-change molecular chain provided between the first electrode and the second electrode,
the first electrode including:
a core made of a first conductive material; and
a side wall formed on a side surface of the core and made of a second conductive material different from the first conductive material,
the second electrode being made of a third conductive material different from the first conductive material, and
the resistance-change molecular chain being bonded to the first conductive material.

2. The molecular memory according to claim 1, wherein
the second conductive material has the same composition as the third conductive material.

3. The molecular memory according to claim 1, wherein
the first conductive material includes tungsten, and
the second and third conductive materials include molybdenum.

4. The molecular memory according to claim 3, wherein
a thiol group is bonded to an end of the resistance-change molecular chain close to the first electrode.

5. The molecular memory according to claim 1, wherein
the first electrode is a wiring that extends in a first direction,
the second electrode is a wiring that extends in a second direction intersecting the first direction, and
the side wall is arranged on both sides of the core in the second direction.

6. The molecular memory according to claim 5, wherein
a plurality of the first electrodes form a first wiring layer,
a plurality of the second electrodes form a second wiring layer, and
the first wiring layer and the second wiring layer are alternately stacked.

7. A molecular memory comprising:
a first wiring made of a first conductive material and extending in a first direction;
a second wiring made of a second conductive material different from the first conductive material and extending in a second direction intersecting the first direction; and
a resistance-change molecular chain provided between the first wiring and the second wiring,
a surface of the first wiring located at the second wiring side having a first region and a second region, the first region facing a center of the second wiring in a width direction, the second region facing an end of the second wiring in the width direction, the first region being closer to the second wiring than the second region.

8. The molecular memory according to claim 7, wherein
the resistance-change molecular chain is bonded to the second conductive material.

9. The molecular memory according to claim 7, wherein
the first conductive material includes molybdenum, and
the second conductive material includes tungsten.

10. The molecular memory according to claim 9, wherein
a thiol group is bonded to an end of the resistance-change molecular chain close to the second wiring.

11. The molecular memory according to claim 7, wherein
a plurality of the first wirings form a first wiring layer,
a plurality of the second wirings form a second wiring layer, and
the first wiring layer and the second wiring layer are alternately stacked.

12. A method of manufacturing a molecular memory comprising:
stacking a first conductive film made of a first conductive material, a sacrificial film, and a second conductive film made of a second conductive material different from the first conductive material in this order;
selectively removing an upper portion of the first conductive film, the sacrificial film, and the second conductive film to form a plurality of first stacked bodies extending in a first direction, and performing side etching on the upper portion of the first conductive film such that the width of the upper portion is less than that of the second conductive film;
embedding a first insulating film between the first stacked bodies;
selectively removing the first insulating film, the second conductive film, the sacrificial film, and the first conductive film to form a plurality of second stacked bodies extending in a second direction intersecting the first direction;
removing the sacrificial film to form a gap;
providing a resistance-change molecular chain in the gap;
embedding a second insulating film between the second stacked bodies in which the resistance-change molecular chain is provided; and
forming a third conductive film extending in the first direction so as to be commonly connected to parts of the second conductive film arranged in the first direction.

13. The method according to claim 12, wherein
the first conductive material includes molybdenum, and
the second conductive material includes tungsten.

14. The method according to claim 13, wherein
a thiol group is connected to one end of the resistance-change molecular chain.
